(19) United States
(12) Patent Application Publication
(10) Pub. No.: US 2026/0324268 A1
(43) Pub. Date: Oct. 15, 2026

(54) DISPLAY DEVICE AND ELECTRONIC APPARATUS

(71) Applicant: Sony Semiconductor Solutions Corporation, Kanagawa (JP)

(72) Inventors: Kenta Hiraga, Kanagawa (JP); Kunihiko Hikichi, Kumamoto (JP); Taku Seto, Kumamoto (JP); Akira Watanabe, Kanagawa (JP); Tomohiko Shimatsu, Kanagawa (JP)

(21) Appl. No.: 19/483,860

(22) PCT Filed: May 13, 2024
(86) PCT No.: PCT/JP2024/017670

§ 371 Date: Nov. 12, 2025

(30) Foreign Application Priority Data
May 29, 2023 (JP) 2023-088110

(51) Int. Cl. H10K 59/80

(52) U.S. Cl. CPC H10K 59/879

(57) ABSTRACT

Display devices structured to facilitate a light extraction function are disclosed. In one example, a display device includes light emitting elements arrayed two-dimensionally and lenses arranged to respectively correspond to the light emitting elements. The respective lenses include a lower portion having a tapered side surface and an upper portion having a convex curved surface.

### TECHNICAL FIELD

The present disclosure relates to a display device and an electronic apparatus including the display device.

### BACKGROUND ART

As a technique for increasing luminance and efficiency of a display device, there is a light condensing technique using a lens. In order to more effectively utilize a light condensing effect of the lens, it is desirable to reduce a distance between adjacent lenses.

For example, Patent Document 1 describes an aspect in which a convex lens member (on-chip micro-convex lens) is used as an optical path control unit, and adjacent convex lens members are in contact with each other.

### CITATION LIST

### Patent Document

Patent Document 1: WO 2020/162355 A

### SUMMARY OF THE INVENTION

### Problems to be Solved by the Invention

However, in the conventional lens, when the distance between the adjacent lenses is reduced, a light extraction function is deteriorated.

An object of the present disclosure is to provide a display device capable of improving a light extraction function and an electronic apparatus including the display device.

### Solutions to Problems

In order to solve the above problem, a display device according to the present disclosure includes:
a plurality of light emitting elements arrayed two-dimensionally; and
a plurality of lenses provided to respectively correspond to the plurality of light emitting elements, in which
the lens includes a lower portion having a tapered side surface and an upper portion having a convex curved surface.

### BRIEF DESCRIPTION OF DRAWINGS

FIGS. 1A and 1B are enlarged cross-sectional views of a lens array of a display device.

FIG. 2 is a plan view of a display device according to one embodiment.

FIGS. 3A and 3B are enlarged plan views illustrating a part of an effective pixel region in FIG. 2.

FIG. 4 is a cross-sectional view taken along line IV-IV in FIG. 3A.

FIG. 5 is a cross-sectional view of a lens array forming process.

FIG. 6 is a cross-sectional view of a lens array forming process.

FIG. 7 is a cross-sectional view of a lens array forming process.

FIG. 8 is a cross-sectional view of a lens array forming process.

FIG. 9 is a cross-sectional view of a lens array forming process.

FIG. 10 is a cross-sectional view of a display device according to a modification.

FIG. 11 is a cross-sectional view of a display device according to a modification.

FIG. 12 is a cross-sectional view of a display device according to a modification.

FIG. 13 is a cross-sectional view of a display device according to a modification.

FIG. 14 is a cross-sectional view of a display device according to a modification.

FIGS. 15A and 15B are plan views of a display device according to a modification.

FIGS. 16A and 16B are plan views of a display device according to a modification.

FIGS. 17A and 17B are plan views of a display device according to a modification.

FIG. 18 is a plan view of a display device according to a modification.

FIGS. 19A, 19B, and 19C are conceptual views for describing a relationship among a normal line LN passing through a center of a light emitting unit, a normal line LN′ passing through a center of a lens member, and a normal line LN″ passing through a center of a wavelength selection unit, respectively.

FIG. 20 is a conceptual view for describing a relationship among the normal line LN passing through the center of the light emitting unit, the normal line LN′ passing through the center of the lens member, and the normal line LN″ passing through the center of the wavelength selection unit.

FIGS. 21A and 21B are conceptual views for describing a relationship among the normal line LN passing through the center of the light emitting unit, the normal line LN′ passing through the center of the lens member, and the normal line LN″ passing through the center of the wavelength selection unit, respectively.

FIG. 22 is a conceptual view for describing a relationship among the normal line LN passing through the center of the light emitting unit, the normal line LN′ passing through the center of the lens member, and the normal line LN″ passing through the center of the wavelength selection unit.

FIG. 23A is a schematic cross-sectional view for describing a first example of a resonator structure.

FIG. 23B is a schematic cross-sectional view for describing a second example of the resonator structure.

FIG. 24A is a schematic cross-sectional view for describing a third example of the resonator structure.

FIG. 24B is a schematic cross-sectional view for describing a fourth example of the resonator structure.

FIG. 25A is a schematic cross-sectional view for describing a fifth example of the resonator structure. FIG. 25B is a schematic cross-sectional view for describing a sixth example of the resonator structure.

FIG. 26 is a schematic cross-sectional view for describing a seventh example of the resonator structure.

FIG. 27A is a front view of a digital still camera. FIG. 27B is a rear view of the digital still camera.

FIG. 28 is a perspective view of a head-mounted display.

FIG. 29 is a perspective view of a television device.

FIG. 30 is a perspective view of a see-through head-mounted display.

FIG. 31 is a perspective view of a smartphone.

FIG. 32A is a view illustrating an internal state of a vehicle as viewed from a rear side to a front side of the vehicle. FIG. 32B is a view illustrating an internal state of the vehicle as viewed from an oblique rear side to an oblique front side of the vehicle.

### MODE FOR CARRYING OUT THE INVENTION

An embodiment and the like of the present disclosure will be described in the following order.
1 Description of overall display device according to present disclosure
2 Background to creation of embodiment of present disclosure
3 One embodiment (example of display device)
4 Modifications
5 Relationship among normal lines passing through centers of each of light emitting unit, lens member, and wavelength selection unit
6 Example of resonator structure
7 Application examples (examples of electronic apparatuses)

The embodiment and the like to be described below is a preferred specific example of the present disclosure, and the content of the present disclosure is not limited to the embodiment and the like. Note that, in the following description, components having substantially the same functional configuration are denoted by the same reference numerals, and redundant description will be omitted as appropriate. Furthermore, in order to prevent the illustration from being complicated, there is a case where only a part of the configuration is denoted by reference numerals, or there is a case where the illustration is simplified or enlarged/reduced.

### 1 Description of Overall Display Device According to Present Disclosure

In the display device according to the present disclosure, a bottom surface of a lower portion of a lens has, for example, a substantially circular shape, a substantially elliptical shape, or a substantially polygonal shape. In order to array a plurality of lenses in a close-packed manner, the bottom surface of the lower portion of the lens preferably has a substantially quadrangular shape or a substantially hexagonal shape. Here, the substantially circular shape, the substantially elliptical shape, or the substantially polygonal shape is not limited to a circular shape, an elliptical shape, or a polygonal shape in a strict sense, and includes a shape that is visually recognized as being close to a circular shape, an elliptical shape, or a polygonal shape. For example, a circular shape, an elliptical shape, or a polygonal shape distorted or deformed within a range of tolerance, error, or the like is included. Specifically, the substantially polygonal shape includes, for example, a polygonal shape with rounded corners and a polygonal shape with notched corners.

In the present disclosure, the tapered shape is not limited to a linear tapered shape in a strict sense in which a diameter changes linearly with respect to a height of the lower portion of the lens and an inclination angle of a side surface of the lower portion is constant, and includes a shape that is visually recognized as being close to the linear tapered shape. For example, a linear tapered shape distorted or deformed within a range of tolerance, error, or the like is included.

In the present disclosure, the tapered side surface has, for example, a substantially circular truncated cone shape, a substantially elliptical truncated cone shape, or a substantially polygonal truncated cone shape. In order to array a plurality of lenses in a close-packed manner, the tapered side surface preferably has a substantially quadrangular truncated cone shape or a substantially hexagonal truncated cone shape. Here, the substantially circular truncated cone shape, the substantially elliptic truncated cone shape, or the substantially polygonal truncated cone shape is not limited to a circular truncated cone shape, an elliptic truncated cone shape, or a polygonal truncated cone shape in a strict sense, and includes a shape that is visually recognized as being close to a circular truncated cone shape, an elliptic truncated cone shape, or a polygonal truncated cone shape. For example, a circular truncated cone shape, an elliptical truncated cone shape, or a polygonal truncated cone shape distorted or deformed within a range of tolerance, error, or the like is included. Specifically, the substantially polygonal truncated cone shape includes, for example, a polygonal truncated cone shape with rounded side ridges and a polygonal truncated cone shape with notched side ridges.

In the present disclosure, “on an object A” in the expression such as “an object B is provided on an object A” indicates a relative positional relationship between the object A and the object B, and is a concept including not only a state in which the object B is directly located on the object A without another object interposed therebetween but also a state in which the object B is located on the object A with at least one another object interposed therebetween.

The display device according to the present disclosure may be provided in an electronic apparatus. For example, the display device according to the present disclosure may be provided in an eyewear device such as a virtual reality (VR) device, a mixed reality (MR) device, and an augmented reality (AR) device, or an electronic view finder (EVF), a small projector, or the like.

### 2 Background to Creation of Embodiment of Present Disclosure

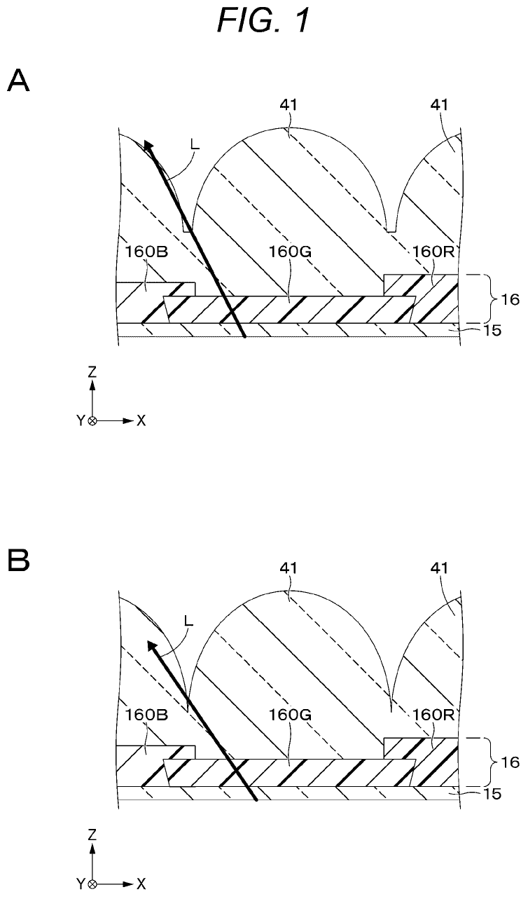

As illustrated in FIG. 1A, when a distance between adjacent lenses 41 is large, light L emitted from a light emitting element 12 easily leaks from a flat portion between the lenses 41. In order to suppress such light leakage and more effectively utilize a light condensing effect of the lens 41, it is desirable to reduce the distance between the adjacent lenses 41.

However, in the lens 41 having a convex curved surface, when the distance between the adjacent lenses 41 is reduced, the side surfaces of the lower portions of the adjacent lenses 41 approach each other as illustrated in FIG. 1B, and the light L is likely to leak from a lower portion of one of the adjacent lenses 41 to a lower portion of the other of the adjacent lenses. Therefore, a function of the lower portion of the lens 41 as a lens is deteriorated, and a light extraction function of the lens 41 is deteriorated.

On the basis of the above findings, the present inventors have conducted intensive studies on a lens capable of suppressing deterioration of the light extraction function of the lens 41 even when the distance between the adjacent lenses is reduced. As a result, the present inventors have found a lens in which an upper portion has a convex curved surface and a lower portion has a tapered side surface.

### 3 One Embodiment

### (Schematic Configuration of Display Device 101)

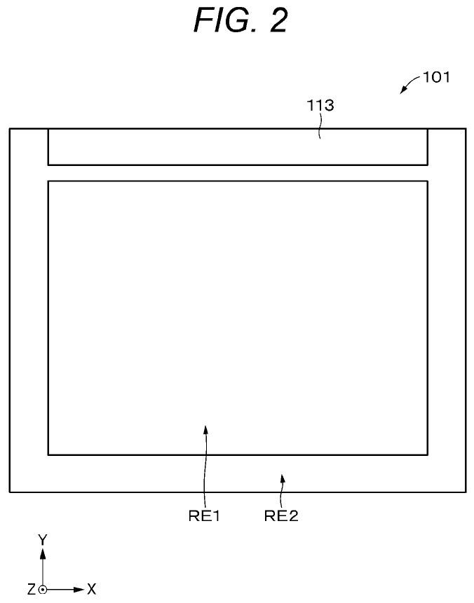

FIG. 2 is a plan view of a display device 101 according to one embodiment. The display device 101 includes an effective pixel region RE1 and a peripheral region RE2 provided around the effective pixel region RE1. The display device 101 may be an organic light emitting diode (OLED) display device. In the present specification, a first direction and a second direction orthogonal to each other in a display surface of the display device 101 is referred to as an X-axis direction and a Y-axis direction, respectively, and a direction perpendicular to the display surface of the display device 101 is referred to as a Z-axis direction. In one embodiment, an example in which the X-axis direction is a horizontal direction of the display surface and the Y-axis direction is a vertical direction of the display surface will be described.

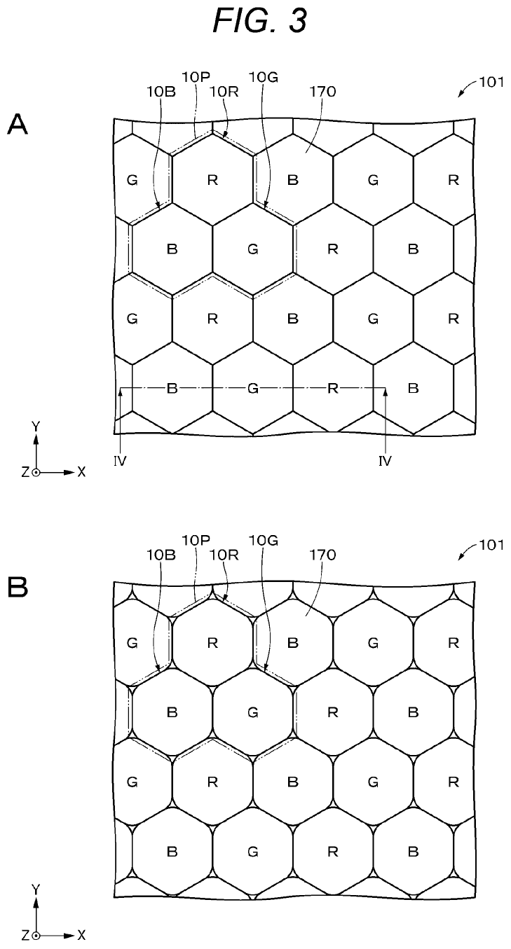

FIG. 3A is an enlarged plan view illustrating a part of the effective pixel region RE1. A plurality of subpixels 10R, a plurality of subpixels 10G, and a plurality of subpixels 10B are provided in the effective pixel region RE1. In the following description, the subpixels 10R, 10G, and 10B may be simply referred to as subpixels 10 in a case where they are collectively referred to without being particularly distinguished. The plurality of subpixels 10 is two-dimensionally arrayed in a prescribed arrangement pattern. In one embodiment, an example in which the array pattern of the plurality of subpixels 10 is a delta arrangement will be described. A pad portion 113, a video display driver (not illustrated), and the like are provided in the peripheral region RE2. A flexible printed circuit (FPC) (not illustrated) may be coupled to the pad portion 113.

The subpixels 10R, 10G, and 10B can emit light of different colors. The subpixel 10R can emit red light. The subpixel 10G can emit green light. The subpixel 10B can emit blue light. In FIG. 3A, sections denoted by symbols “R”, “G”, and “B” represent the subpixel 10R, the subpixel 10G, and the subpixel 10B, respectively.

One pixel 10P may include three adjacent subpixels 10R, 10G, and 10B. The configuration of the one pixel 10P, however, is not limited to this example. The subpixel 10 may have a hexagonal shape in plan view as illustrated in FIG. 3A, or may have a hexagonal shape with rounded corners as illustrated in FIG. 3B. Although outlines of the subpixels 10R, 10G, and 10B are illustrated in FIGS. 3A and 3B, there is not always a clear boundary among the adjacent subpixels 10R, 10G, and 10B.

### [Layer Configuration of Display Device 101]

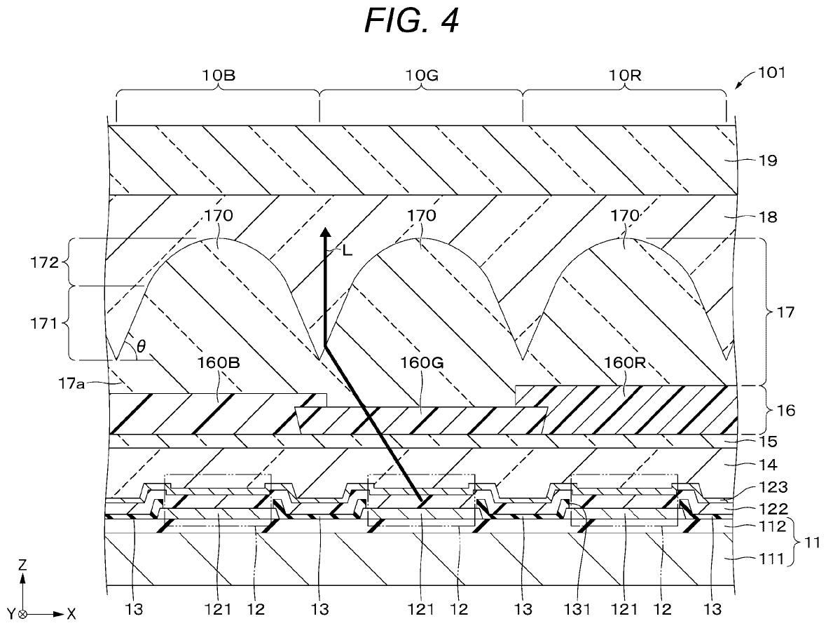

FIG. 4 is a cross-sectional view taken along line IV-IV in FIG. 3. The display device 101 includes a drive substrate 11, a plurality of light emitting elements 12, an insulating layer 13, a protective layer 14, a flattening layer 15, a color filter 16, a lens array 17, a filling resin layer 18, and a substrate 19.

In the present specification, out of both surfaces of each layer configuring the display device 101, a surface on the display surface side (top side) of the display device 101 may be referred to as a first surface (upper surface), and a surface on the opposite side (bottom side) to the display surface of the display device 101 may be referred to as a second surface (lower surface). In the present specification, plan view means plan view when an object is viewed from a direction perpendicular to the first surface.

### (Drive Substrate 11)

The drive substrate 11 is a so-called backplane and can drive a plurality of light emitting elements 12. The drive substrate 11 includes, for example, a substrate 111 and an insulating layer 112 in order.

A plurality of drive circuits (not illustrated), a plurality of wirings (not illustrated), and the like are provided on the first surface side of the substrate 111. The substrate 111 may be, for example, a semiconductor substrate in which a transistor or the like is easily formed, or may be a glass substrate or a resin substrate having low moisture and oxygen permeability. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one kind selected from a group including polymethyl methacrylate, polyvinyl alcohol, polyvinyl phenol, polyethersulfone, polyimide, polycarbonate, polyethylene terephthalate, polyethylene naphthalate, and the like.

The insulating layer 112 is provided on the first surface of the substrate 111, and covers a plurality of drive circuits, a plurality of wirings, and the like. The plurality of wirings may be coupled to the pad portion 113. The insulating layer 112 includes a plurality of contact portions (not illustrated) therein. The plurality of contact portions electrically couples the light emitting elements 12 and the drive circuits or the wirings. The contact portion includes, for example, at least one kind of metal selected from a group including copper (Cu), titanium (Ti), and the like.

The insulating layer 112 may be an organic insulating layer, an inorganic insulating layer, or a laminate formed with these layers. The organic insulating layer includes, for example, at least one kind selected from a group including a polyimide resin, an acrylic resin, a novolac resin, and the like. The inorganic insulating layer includes, for example, at least one kind selected from a group including silicon oxide (SiOₓ), silicon nitride (SiNₓ), silicon oxynitride (SiOₓN_{y}), and the like.

### (Light Emitting Element 12)

The light emitting element 12 can emit white light under the control of the drive circuit or the like. The light emitting element 12 may be an organic light emitting diode element (OLED element). The light emitting element 12 is included in each color of the subpixels 10R, 10G, and 10B.

The plurality of light emitting elements 12 is two-dimensionally arranged on the first surface of the drive substrate 11 in a prescribed arrangement pattern. The prescribed arrangement pattern is as described as the prescribed arrangement pattern of the plurality of subpixels 10. The light emitting element 12 includes a first electrode 121, an OLED layer 122, and a second electrode 123 in order on the first surface of the drive substrate 11.

### (First Electrode 121)

The first electrode 121 is provided on the second surface side of the OLED layer 122. The first electrode 121 is an individual electrode individually provided in the plurality of light emitting elements 12 in the effective pixel region RE1. That is, the first electrode 121 is divided between the light emitting elements 12 adjacent in an in-plane direction of the first surface of the drive substrate 11 in the effective pixel region RE1. The first electrode 121 is an anode. When a voltage is applied between the first electrode 121 and the second electrode 123, holes are injected from the first electrode 121 into the OLED layer 122.

The first electrode 121 may be configured using, for example, a metal layer, or may be configured using a metal layer and a transparent conductive oxide layer. In a case where the first electrode 121 is configured using a metal layer and a transparent conductive oxide layer, the transparent conductive oxide layer is preferably provided on the OLED layer 122 side from the viewpoint of placing a layer with a high work function adjacent to the OLED layer 122.

The metal layer may have a function as a reflective layer that reflects light emitted from the OLED layer 122. The metal layer includes, for example, at least one kind of metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include at least one kind of metal element described above as a constituent element of an alloy. Specific examples of the alloy include an aluminum alloy and a silver alloy. Specific examples of the aluminum alloy include, for example, AlNd and AlCu.

An underlayer (not illustrated) may be provided adjacent to the second surface side of the metal layer. The underlayer may improve crystalline orientation of the metal layer at the time of formation of the metal layer. The underlayer includes, for example, at least one kind of metal element selected from a group including titanium (Ti) and tantalum (Ta). The underlayer may include at least one kind of metal element described above as a constituent element of an alloy.

The transparent conductive oxide layer includes a transparent conductive oxide. The transparent conductive oxide includes, for example, at least one kind selected from a group including an indium-containing transparent conductive oxide (hereinafter, referred to as an “indium-based transparent conductive oxide”), a tin-containing transparent conductive oxide (hereinafter, referred to as a “tin-based transparent conductive oxide”), and a zinc-containing transparent conductive oxide (hereinafter, referred to as a “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO), or fluorine-doped indium oxide (IFO). Among these transparent conductive oxides, indium tin oxide (ITO) is particularly preferable. This is because indium tin oxide (ITO) has a particularly low barrier for hole injection into the OLED layer 122 in terms of a work function, such that a drive voltage of the display device 101 can be particularly reduced. The tin-based transparent conductive oxide includes, for example, tin oxide, antimony-doped tin oxide (ATO), or fluorine-doped tin oxide (FTO). The zinc-based transparent conductive oxide includes, for example, zinc oxide, aluminum-doped zinc oxide (AZO), boron-doped zinc oxide, or gallium-doped zinc oxide (GZO).

### (OLED Layer 122)

The OLED layer 122 can emit white light. The OLED layer 122 is provided between the plurality of first electrodes 121 and one second electrode 123. The OLED layer 122 is connected between the light emitting elements 12 adjacent in the in-plane direction of the first surface of the drive substrate 11 in the effective pixel region RE1, and is a layer common to the plurality of light emitting elements 12 in the effective pixel region RE1.

The OLED layer 122 may be configured using a laminate including an organic light emitting layer, and in this case, some layers (for example, electron injection layers) of the laminate may be inorganic layers. The OLED layer 122 may be an OLED layer including a single-layer light emitting unit, may be an OLED layer including a two-layer light emitting unit (tandem structure), or may be an OLED layer having another structure. The OLED layer including a single-layer light emitting unit has a configuration in which a hole injection layer, a hole transport layer, a red light emitting layer, a light emitting separation layer, a blue light emitting layer, a green light emitting layer, an electron transport layer, and an electron injection layer are laminated in this order from the first electrode 121 toward the second electrode 123, for example. The OLED layer including a two-layer light emitting unit has a configuration in which a hole injection layer, a hole transport layer, a blue light emitting layer, an electron transport layer, a charge generation layer, a hole transport layer, a yellow light emitting layer, an electron transport layer, and an electron injection layer are laminated in this order from the first electrode 121 toward the second electrode 123, for example.

The hole injection layer can enhance efficiency of hole injection into each light emitting layer, and suppress leakage. The hole transport layer can enhance efficiency of hole transport to each light emitting layer. The electron injection layer can enhance efficiency of electron injection into each light emitting layer. The electron transport layer can enhance efficiency of electron transport to each light emitting layer. The light emitting separation layer is a layer for adjusting injection of carriers into each light emitting layer, and light emitting balance of each color is adjusted by injecting electrons or holes into each light emitting layer via the light emitting separation layer. The charge generation layer can respectively supply electrons and holes to two light emitting layers provided so as to sandwich the charge generation layer.

In response to application of an electric field to each of the red light emitting layer, the green light emitting layer, the blue light emitting layer, and the yellow light emitting layer, recombination occurs between the holes injected from the first electrodes 121 or the charge generation layer and the electrons injected from the second electrode 123 or the charge generation layer, and red light, green light, blue light, and yellow light can be emitted.

### (Second Electrode 123)

The second electrode 123 is provided on the first surface side of the OLED layer 122. The second electrode 123 is connected between the light emitting elements 12 adjacent in the in-plane direction of the first surface of the drive substrate 11 in the effective pixel region RE1, and is an electrode common to the plurality of light emitting elements 12 in the effective pixel region RE1.

The second electrode 123 is a cathode. When a voltage is applied between the first electrode 121 and the second electrode 123, electrons are injected from the second electrode 123 into the OLED layer 122. The second electrode 123 has translucency with respect to white light emitted from the OLED layer 122. The second electrode 123 is preferably a transparent electrode that is transparent to visible light. In the present specification, visible light refers to light in a wavelength range of 360 nm or more and 830 nm.

The second electrode 123 preferably includes a material having as high translucency as possible and a low work function in order to enhance luminous efficiency. The second electrode 123 includes, for example, at least one of a metal layer or a transparent conductive oxide layer. More specifically, the second electrode 123 includes a single-layer film of a metal layer or a transparent conductive oxide layer, or a multilayer film of a metal layer and a transparent conductive oxide layer. In a case where the second electrode 123 is configured using a multilayer film, the metal layer may be provided on the OLED layer 122 side, or the transparent conductive oxide layer may be provided on the OLED layer 122 side. However, from the viewpoint of placing a layer with a low work function adjacent to the OLED layer 122, the metal layer is preferably provided on the OLED layer 122 side.

The metal layer includes, for example, at least one kind of metal element selected from a group including magnesium (Mg), aluminum (Al), silver (Ag), calcium (Ca), and sodium (Na). The metal layer may include at least one kind of metal element described above as a constituent element of an alloy. Specific examples of the alloy include an MgAg alloy, an MgAl alloy, an AlLi alloy, or the like. The transparent conductive oxide layer includes a transparent conductive oxide. As the transparent conductive oxide, a material similar to the transparent conductive oxide of the above-described first electrode 121 can be exemplified.

### (Insulating Layer 13)

The insulating layer 13 is provided in a portion between the separated first electrodes 121 on the first surface of the drive substrate 11. The insulating layer 13 can insulate the first electrodes 121 adjacent in the in-plane direction of the first surface of the drive substrate 11 from each other. The insulating layer 13 has a plurality of openings 131. Each of the plurality of openings 131 is provided to correspond to each light emitting element 12. Each of the plurality of openings 131 may be provided on the first surface (surface on the OLED layer 122 side) of each of the first electrodes 121. The first electrodes 121 and the OLED layer 122 are in contact with each other via the openings 131.

The insulating layer 13 may be an organic insulating layer, an inorganic insulating layer, or a laminate thereof. The organic insulating layer includes, for example, at least one kind selected from a group including a polyimide resin, an acrylic resin, a novolac resin, and the like. The inorganic insulating layer includes, for example, at least one kind selected from a group including silicon oxide (SiOₓ), silicon nitride (SiNₓ), silicon oxynitride (SiOₓN_{y}), and the like.

### (Protective Layer 14)

The protective layer 14 is provided on the first surface of the second electrode 123 and covers the plurality of light emitting elements 12. The protective layer 14 has translucency with respect to white light emitted from the light emitting element 12. The protective layer 14 can protect the plurality of light emitting elements 12 and the like. For example, the protective layer 14 can suppress moisture ingress into the plurality of light emitting elements 12 and the like from an external environment. Furthermore, in a case where the second electrode 123 is configured using a metal layer, the protective layer 14 may have a function to suppress oxidation of the metal layer.

The protective layer 14 includes, for example, at least one of an inorganic material or an organic material having low moisture absorptivity. The protective layer 14 may have a single-layer structure or a multilayer structure. In a case where a thickness of the protective layer 14 is increased, the multilayer structure is preferable. This is for alleviating an internal stress in the protective layer 14. The inorganic material includes, for example, at least one kind selected from a group including silicon oxide (SiOₓ), silicon nitride (SiNₓ), silicon oxynitride (SiOₓN_{y}), titanium oxide (TiOₓ), aluminum oxide (AlOₓ), and the like. The organic material includes a cured product of at least one kind of resin selected from a group including a thermosetting resin, a photosensitive resin, and the like, for example. The photosensitive resin includes, for example, an ultraviolet curable resin. Specifically, the organic material includes, for example, at least one kind selected from a group including an acrylic resin, a polyimide resin, a novolac resin, an epoxy resin, a norbornene resin, a parylene resin, and the like.

The protective layer 14 preferably includes a deposited layer on which an atomic layer is deposited. The deposited layer may be an atomic layer deposition (ALD) layer. When the protective layer 14 includes a deposited layer, it is possible to enhance the moisture ingress suppression effect of the protective layer 14. The deposited layer includes, for example, a metal oxide or a metal nitride. The metal oxide includes, for example, aluminum oxide (AlOₓ) or titanium oxide (TiOₓ). The metal nitride includes, for example, titanium nitride (TiNₓ).

### (Flattening Layer 15)

The flattening layer 15 is provided on the first surface of the protective layer 14. The flattening layer 15 can fill irregularities of the first surface of the protective layer 14 and form a flat first surface above the protective layer 14. The flattening layer 15 has translucency with respect to white light emitted from the light emitting element 12. The flattening layer 15 includes, for example, at least one of an organic material or an inorganic material.

The organic material includes, for example, a cured product of a photosensitive resin composition. The photosensitive resin composition may include either a positive photosensitive resin composition or a negative photosensitive resin composition. Specifically, the photosensitive resin composition includes, for example, at least one kind selected from a group including polyimide, a polyimide precursor, polybenzoxazole, a polybenzoxazole precursor, an acrylic resin, a phenolic resin, a siloxane-based resin, and the like. As the inorganic material, a material similar to the inorganic material of the protective layer 14 can be exemplified.

### (Color Filter 16)

The color filter 16 is a so-called on-chip color filter (OCCF). The color filter 16 is provided above the plurality of light emitting elements 12. More specifically, the color filter 16 is provided on the first surface of the flattening layer 15 in the effective pixel region RE1. The color filter 16 includes, for example, a plurality of colored layers 160R, a plurality of colored layers 160G, and a plurality of colored layers 160B. In the following description, the colored layer 160R, the colored layer 160G, and the colored layer 160B may be simply referred to as the colored layer 160 in a case where the colored layer 160R, the colored layer 160G, and the colored layer 160B are collectively referred to without being particularly distinguished.

The plurality of colored layers 160 is two-dimensionally arranged on the first surface of the flattening layer 15 in a prescribed arrangement pattern. The prescribed arrangement pattern is as described as the prescribed arrangement pattern of the plurality of subpixels 10. Each colored layer 160 is provided above the light emitting element 12. The subpixel 10R includes a light emitting element 12 and a colored layer 160R provided above the light emitting element 12. The subpixel 10G includes a light emitting element 12 and a colored layer 160G provided above the light emitting element 12. The subpixel 10B includes a light emitting element 12 and a colored layer 160B provided above the light emitting element 12.

The colored layer 160R has a red color. The colored layer 160R can transmit a red light component out of the white light emitted from the light emitting element 12 and absorb a visible light component other than the red light. The colored layer 160G has a green color. The colored layer 160G can transmit a green light component out of the white light emitted from the light emitting element 12 and absorb a visible light component other than the green light. The colored layer 160B has a blue color. The colored layer 160B can transmit a blue light component out of the white light emitted from the light emitting element 12 and absorb a visible light component other than the blue light.

The colored layer 160R includes a red color resist, for example. The colored layer 160G includes a green color resist, for example. The colored layer 160B includes a blue color resist, for example.

### (Lens Array 17)

The lens array 17 is provided on the first surface of the color filter 16. The lens array 17 includes a plurality of lenses 170. The lens array 17 may further include a base layer 17a. Each lens 170 is capable of condensing light emitted upward from the light emitting element 12 in a front direction. The plurality of lenses 170 is a so-called on-chip microlens (OCL), and is two-dimensionally arranged on the first surface of the color filter 16 in a prescribed arrangement pattern. The prescribed arrangement pattern is as described as the prescribed arrangement pattern of the plurality of subpixels 10.

The plurality of lenses 170 is arranged such that the lens surfaces are on the side opposite to the light emitting element 12 side. One lens 170 is provided above one light emitting element 12. The lens 170 includes a lower portion 171 and an upper portion 172 provided on the lower portion 171.

The lower portion 171 of the lens 170 has a tapered side surface. The tapered side surface is tapered toward a top portion of the lens 170. A lower limit value of an inclination angle 0 of the side surface of the lower portion 171 is preferably 45°<θ from the viewpoint of suppressing a decrease in the light condensing effect. An upper limit value of the inclination angle θ of the side surface of the lower portion 171 is, for example, θ<90°, θ<86°, θ<82°, or θ<80°. The numerical range of the inclination angle 0 of the side surface of the lower portion 171 may be prescribed by any one of the upper limit value and the lower limit value, and for example, 45°<θ<90°, 45°<θ<86°, 45°<θ<82°, and 45°<θ<80°.

The inclination angle 0 of the side surface of the lower portion 171 is obtained as follows. First, a cross section of the display device 101 (a cross section parallel to a thickness direction of the display device 101) is cut out by cryo-focused ion beam (FIB) processing or the like to prepare a thin piece. At this time, the cross section is cut out so as to include a central axis of the lens 170. Subsequently, the prepared thin piece is observed under a transmission electron microscope (TEM) to acquire a cross-sectional TEM image. Next, in the acquired cross-sectional TEM image, the inclination angle θ of the side surface of the lower portion 171 is measured.

The bottom surface of the lower portion 171, that is, the bottom surface of the lens 170 preferably has a hexagonal shape in plan view as illustrated in FIG. 3A. The bottom surface of the lower portion 171 may have a hexagonal shape with rounded corners as illustrated in FIG. 3B. Since the bottom surface of the lower portion 171 has a hexagonal shape or a hexagonal shape with rounded corners, an area of a gap between the adjacent lenses 170 can be reduced as compared with the case where the bottom surface of the lower portion 171 has a circular shape (see FIG. 18). The tapered side surface preferably has a substantially hexagonal truncated cone shape.

FIG. 3A illustrates an example in which the bottom surface shape of the lens 170 and the shape of the subpixel 10 are the same in plan view, and the sizes of the bottom surface of the lens 170 and the subpixel 10 are the same. However, the bottom surface shape of the lens 170 and the shape of the subpixel 10 may be different, or the sizes of the bottom surface of the lens 170 and the subpixel 10 may be different.

It is preferable that sides (peripheral edges) of the bottom surfaces of the adjacent lenses 170 are in contact with each other in plan view. With this arrangement, the gap between the adjacent lenses 170 can be reduced. Therefore, light leakage from the gap between the adjacent lenses 170 can be suppressed.

The upper portion 172 is provided on a side where a width of the tapered lower portion 171 is narrowed. The upper portion 172 has a convex curved surface. Examples of the convex curved surface include, for example, but are not limited to, a substantially parabolic shape, a substantially hemispherical shape, a substantially semielliptical shape, or the like. Here, the substantially paraboloid shape, the substantially hemispherical shape, or the substantially semielliptical shape is not limited to a parabolic shape, a hemispherical shape, or a semielliptical shape in a strict sense, and includes a shape that is visually recognized as being close to a paraboloid shape, a hemispherical shape, or a semielliptical shape. For example, the shape includes a parabolic shape, a hemispherical shape, or a semielliptical shape that is distorted or deformed within a range of tolerance, error, or the like. The upper portion 172 and the lower portion 171 are preferably smoothly connected.

A refractive index n₁ of the lens 170, that is, the refractive indexes of the lower portion 171 and the upper portion 172 are preferably larger than a refractive index n₂ of the filling resin layer 18. Since the refractive index n₁ of the lens 170 is larger than the refractive index n₂ of the filling resin layer 18, light can be refracted by the tapered surface of the lower portion 171 and the convex curved surface of the upper portion 172 to rise in the front direction. Therefore, the light extraction function can be improved. Herein, the refractive indexes n₁ and n₂ represent refractive indexes for light having a wavelength of 589.3 nm (D line of sodium).

The lower portion 171 and the upper portion 172 include, for example, different materials or the same material, and preferably the same material. Since the lower portion 171 and the upper portion 172 include the same material, it is possible to reduce types of materials required for manufacturing the display device 101. Therefore, the productivity of the display device 101 can be improved, and the manufacturing cost of the display device 101 can be reduced. In addition, since the lower portion 171 and the upper portion 172 include the same material, the refractive indexes of the lower portion 171 and the upper portion 172 are aligned, such that reflection at an interface between the lower portion 171 and the upper portion 172 can also be suppressed.

The lower portion 171 and the upper portion 172 include, for example, an inorganic material or a polymer resin transparent to the visible light. The inorganic material includes, for example, silicon oxide (SiOₓ). The polymer resin includes, for example, a photosensitive resin such as an ultraviolet curable resin.

The base layer 17a is provided between the plurality of lenses 170 and the color filter 16. The base layer 17a includes, for example, the same material as the lower portion 171 of the lens 170. Note that the base layer 17a is provided as necessary, and may be provided or may not be provided.

### (Filling Resin Layer 18)

The filling resin layer 18 is provided on the first surface of the lens array 17 and fills a space between the lens array 17 and the substrate 19. The filling resin layer 18 has translucency with respect to light of each color emitted from the color filter 16. The filling resin layer 18 has a function as an adhesive layer for bonding the lens array 17 and the substrate 19.

The filling resin layer 18 includes, for example, a cured product of a curable resin. The curable resin includes, for example, at least one kind selected from a group including a thermosetting resin, an ultraviolet curable resin, and the like. Note that the filling resin layer 18 is not limited to a thermosetting resin and an ultraviolet curable resin, and may include other kind of curable resin that is neither a thermosetting resin nor an ultraviolet curable resin.

### (Substrate 19)

The substrate 19 is provided on the first surface of the filling resin layer 18. The substrate 19 seals the first surface of the drive substrate 11 on which the plurality of light emitting elements 12 and the like is provided. The substrate 19 has translucency with respect to light of each color emitted from the color filter 16. The substrate 19 is a glass substrate, for example.

### [Method for Manufacturing Display Device 101]

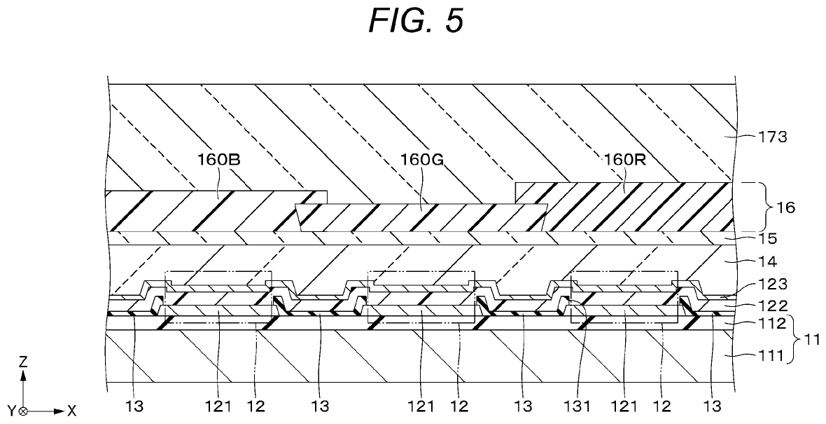

Hereinafter, an example of the method for manufacturing the display device 101 according to one embodiment will be described with reference to FIGS. 5 to 9.

### (Process of Forming First Electrode 121)

First, a metal layer and a metal oxide layer are sequentially formed on the first surface of the drive substrate 11 by, for example, a sputtering method, and then the metal layer and the metal oxide layer are patterned by, for example, a photolithography technique. With this arrangement, the plurality of first electrodes 121 is formed on the first surface of the drive substrate 11.

### (Process of Forming Insulating Layer 13)

Next, the insulating layer 13 is formed on the first surface of the drive substrate 11 in such a way as to cover the plurality of first electrodes 121 by, for example, a chemical vapor deposition (CVD) method. Next, the insulating layer 13 is processed by a photolithography technique to form the openings 131 on the first surface of each of the first electrodes 121.

### (Process of Forming OLED Layer 122)

Next, by a vapor deposition method, for example, a hole transport layer, a red light emitting layer, a light emitting separation layer, a blue light emitting layer, a green light emitting layer, an electron transport layer, and an electron injection layer are laminated in this order on the first surfaces of the plurality of first electrodes 121 and on the first surface of the insulating layer 13. With this arrangement, the OLED layer 122 is formed.

### (Process of Forming Second Electrode 123)

Next, the second electrode 123 is formed on the first surface of the OLED layer 122 by a vapor deposition method or a sputtering method, for example. With this arrangement, the plurality of light emitting elements 12 is formed on the first surface of the drive substrate 11.

### (Process of Forming Protective Layer 14)

Next, the protective layer 14 is formed on the first surface of the second electrode 123 by, for example, the CVD method or the vapor deposition method.

### (Process of Forming Flattening Layer 15)

Next, the resin composition is applied onto the first surface of the protective layer 14, and then cured by, for example, light irradiation or heating to form the flattening layer 15.

(process of Forming Color Filter 16)

Next, a green color resist is applied onto the first surface of the flattening layer 15, and after pattern exposure by irradiation with ultraviolet rays through a photomask, development is performed to form the green colored layer 160G. Next, a red color resist is applied onto the first surface of the flattening layer 15, and after pattern exposure by irradiation with ultraviolet rays through a photomask, development is performed to form the red colored layer 160R. Next, a blue color resist is applied onto the first surface of the flattening layer 15, and after pattern exposure by irradiation with ultraviolet rays through a photomask, development is performed to form the blue colored layer 160B. With this arrangement, the color filter 16 is formed on the first surface of the flattening layer 15.

(process of Forming Lens Array 17)

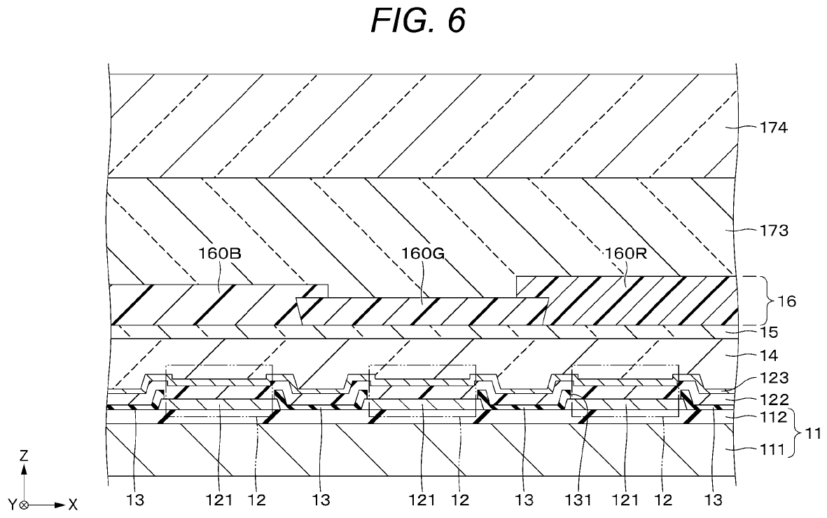

Next, for example, a first photosensitive resin as a first lens material is applied to the first surface of the color filter 16 by a spin coating method and cured by light irradiation to form a first photosensitive resin layer 173 as a first lens material layer as illustrated in FIG. 5. Next, a second photosensitive resin as a second lens material is applied to the first surface of the first photosensitive resin layer 173 by, for example, a spin coating method and cured by light irradiation to form a second photosensitive resin layer 174 as a second lens material layer as illustrated in FIG. 6.

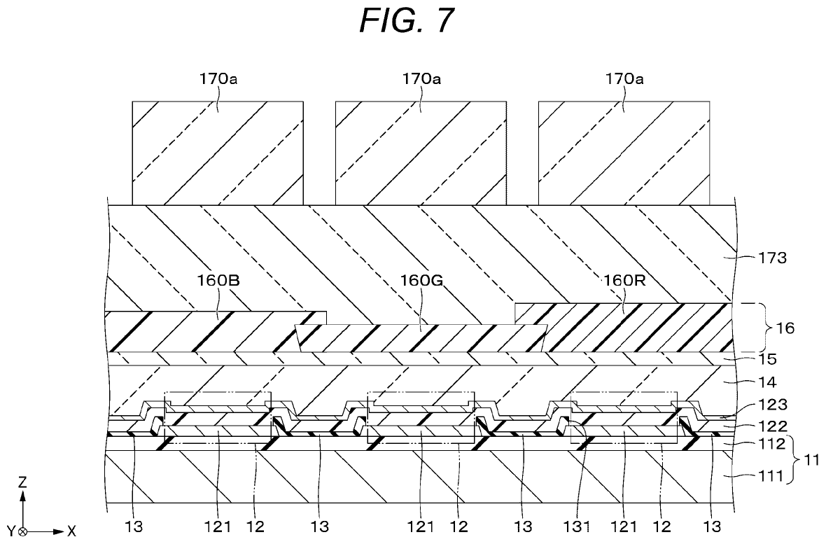

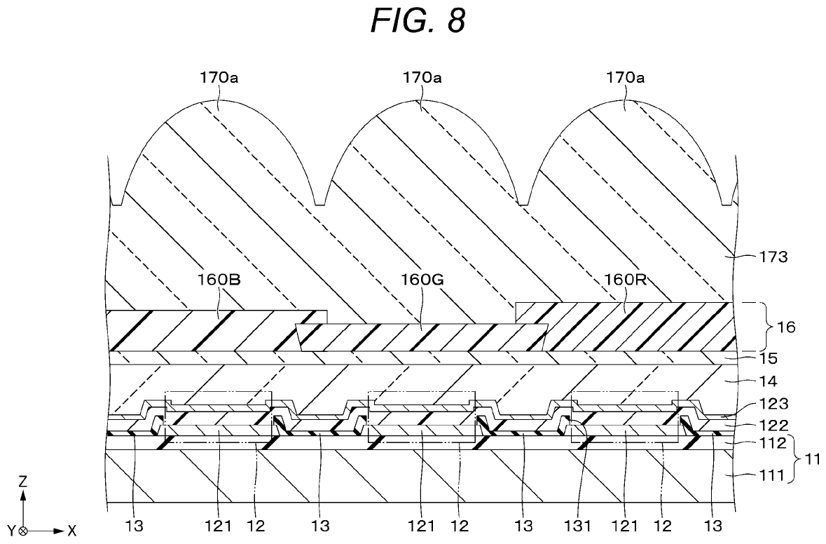

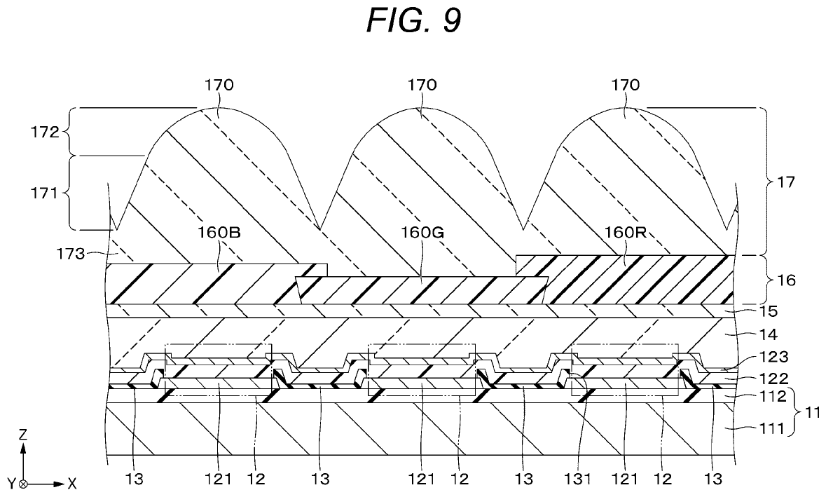

Next, the second photosensitive resin layer 174 is patterned by, for example, a photolithography technique to form a plurality of structures 170a on the first surface of the first photosensitive resin layer 173 as illustrated in FIG. 7. The structure 170a is, for example, a hexagonal columnar body. Next, as illustrated in FIG. 8, the plurality of structures 170a is melted into a convex curved surface by, for example, a reflow process (heating process) and then cured. Next, the convex curved surfaces of the plurality of structures 170a and the first photosensitive resin layer 173 located between the structures 170a are etched back by, for example, anisotropic dry etching. With this arrangement, a plurality of lenses 170 is formed as illustrated in FIG. 9.

### (Process of Sealing)

Next, the drive substrate 11 and the substrate 19 are bonded as follows by, for example, a one drop fill (ODF) method. A filling resin is applied to the first surface of the lens array 17, and the substrate 19 is placed on the filling resin. After the placement, the drive substrate 11 and the substrate 19 are bonded to each other via the filling resin, for example, by applying heat to the filling resin or irradiating the filling resin with ultraviolet rays to cure the filling resin. With this arrangement, the display device 101 is sealed. Note that, in a case where the filling resin includes both the thermosetting resin and the ultraviolet curable resin, the filling resin may be irradiated with ultraviolet rays to be temporarily cured, and then heat may be applied to the filling resin to finally cure the filling resin. Through the above, the display device 101 illustrated in FIG. 4 is obtained.

### [Operations and Effects]

In the display device 101 according to one embodiment, since the lower portion 171 has a tapered side surface, even if the distance between the adjacent lenses 41 is reduced, the approach of the side surfaces of the lower portions 171 of the adjacent lenses 41 can be suppressed. Therefore, the light L hardly leaks from the lower portion 171 of one of the adjacent lenses 41 to the lower portion 171 of the other of the adjacent lenses 41, and it is possible to suppress deterioration of the function of the lower portion 171 of the lens 41 as a lens. It is therefore possible to improve the light extraction function of the lens 41.

As a method of forming a lens, there is a method of forming a convex curved surface lens only by a reflow process. However, in this method, in a case where the distance between the adjacent lenses is narrowed, the material for forming the lenses flows during the reflow process, valley portions between the lenses are filled, and the lens shape collapses.

On the other hand, in the display device according to one embodiment, as illustrated in FIG. 8, the plurality of structures 170a is melted and formed into convex curved surfaces by the reflow process, and then, as illustrated in FIG. 9, the convex curved surfaces of the plurality of structures 170a and the first photosensitive resin layer 173 located between the structures 170a are etched back by anisotropic dry etching or the like. Therefore, shape collapse of the lens 170 can be suppressed.

### <4 Modifications>

### [Modification 1]

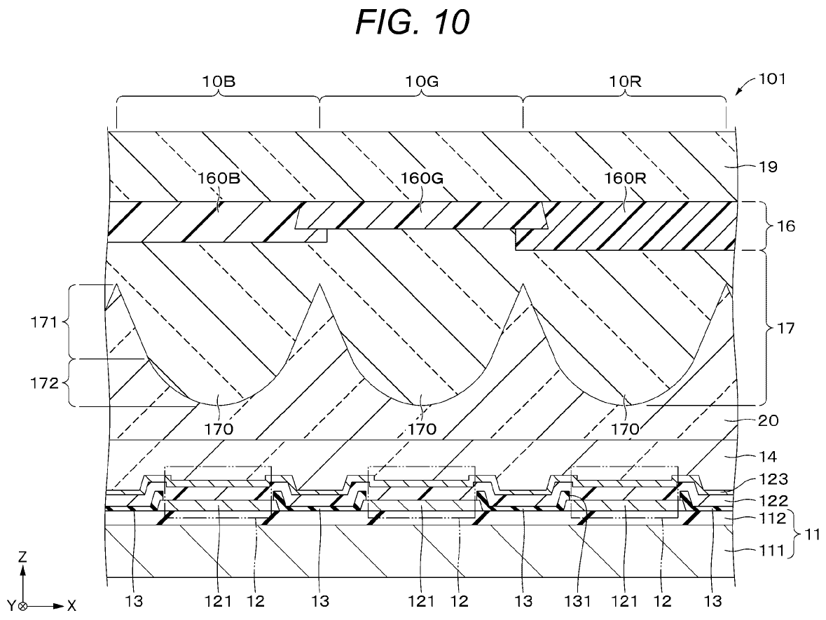

In one embodiment, an example in which the color filter 16 is an on-chip color filter has been described. However, the configuration of the display device 101 is not limited to this example. For example, as illustrated in FIG. 10, the color filter 16 and the lens array 17 may be sequentially provided on the second surface of the substrate 19. In this case, the plurality of lenses 170 may be arranged such that the lens surfaces are on the light emitting element 12 side. A filling resin layer 20 may be provided between the protective layer 14 and the lens array 17. The refractive index n₁ of the lens 170 is preferably larger than the refractive index n₂ of the filling resin layer 20. Since the refractive index n₁ of the lens 170 is larger than the refractive index n₂ of the filling resin layer 18, light can be refracted by the tapered surface of the lower portion 171 and the convex curved surface of the upper portion 172 to rise in the front direction. Therefore, the light extraction function can be improved.

The display device 101 having the above configuration is prepared, for example, as follows. The color filter 16 and the lens array 17 are sequentially laminated on the second surface of the substrate 19. After the protective layer 14 is formed on the first surface of the second electrode 123, a filling resin is applied to the first surface of the protective layer 14, and the substrate 19 is placed on the filling resin such that the lens array 17 is on the filling resin side. After the placement, the drive substrate 11 and the substrate 19 are bonded to each other via the filling resin, for example, by applying heat to the filling resin or irradiating the filling resin with ultraviolet rays to cure the filling resin.

In the manufacturing process of the display device 101 according to one embodiment, the lens array 17 is formed on the drive substrate 11 side. Therefore, the process of forming the lens array 17 and the like are desirably a low-temperature process in consideration of deterioration of the characteristics of the OLED layer 122 due to heating. On the other hand, in the manufacturing process of the display device 101 according to Modification 1, the lens array 17 is formed on the substrate 19 side. Therefore, in the process of forming the lens array 17 and the like, it is not necessary to consider deterioration in characteristics of the OLED layer 122 due to heating, and it is not necessary to perform a low-temperature process. Therefore, the display device 101 can be easily manufactured.

### [Modification 2]

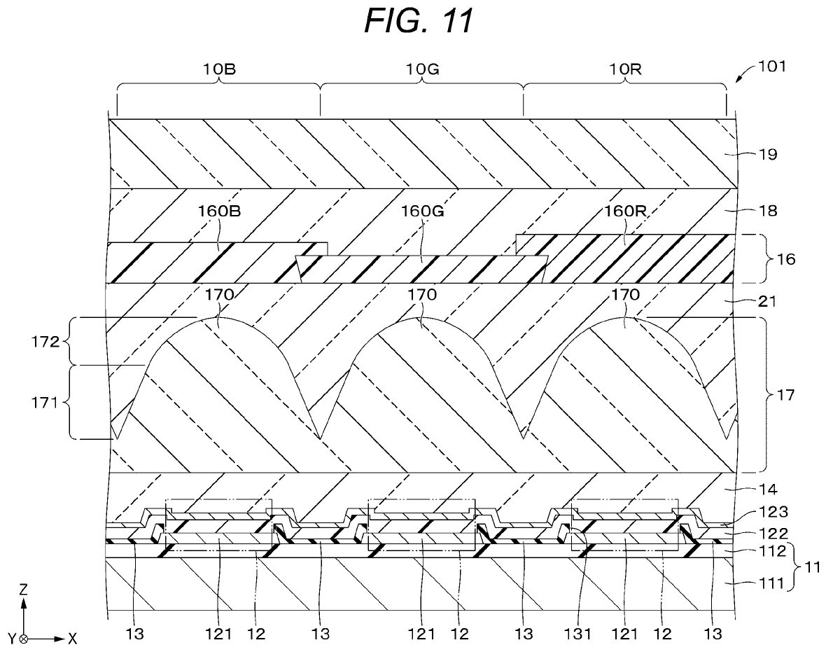

As illustrated in FIG. 11, the color filter 16 may be provided on the upper side of the lens array 17. For example, the lens array 17 may be provided between the plurality of light emitting elements 12 and the color filter 16. In this case, the lens array 17, the flattening layer 21, the color filter 16, the filling resin layer 18, and the substrate 19 may be provided in order on the first surface of the protective layer 14.

In the display device 101 according to Modification 2, since the distance from the light emitting element 12 to the lens array 17 can be shortened, the amount of light incident on the lens 170 from the light emitting element 12 can be increased. It is therefore possible to increase front luminance of the display device 101.

### [Modification 3]

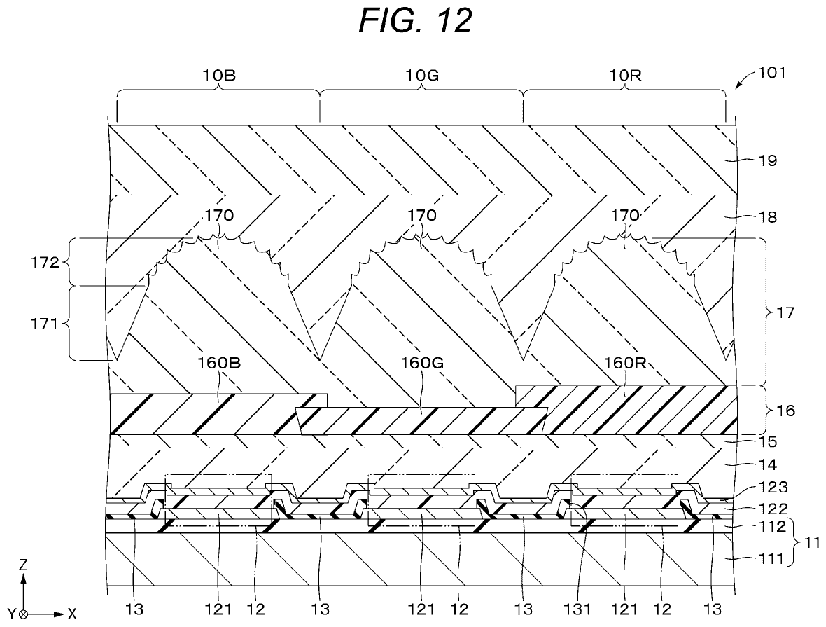

As illustrated in FIG. 12, the lens 170 may have fine irregularities on the lens surface. The upper portion 172 of the lens 170 may have the irregularities, or both upper portion 172 and lower portion 171 of the lens 170 may have the irregularities. Since the lens 170 has fine irregularities on the lens surface, light emitted from the lens 170 can be scattered by the fine irregularities. Therefore, the light extraction function can be improved.

### [Modification 4]

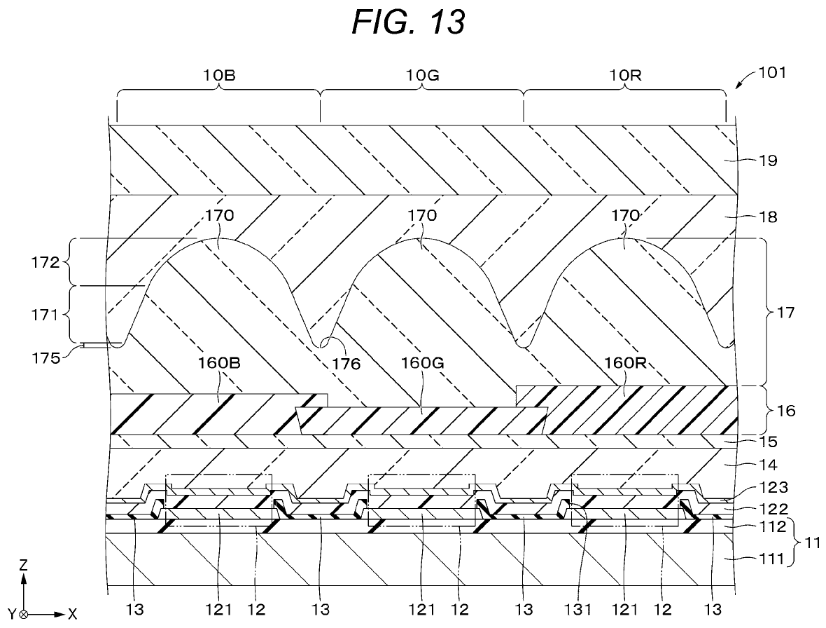

As illustrated in FIG. 13, the lens 170 may further include a bottom portion 175. The bottom portion 175 is provided below the lower portion 171. The bottom portion 175 preferably has a curved side surface. The curved side surface has a gentler inclination than the tapered side surface of the lower portion 171. A groove 176 is formed between the bottom portions 175 of the adjacent lenses 170. The cross-sectional shape of the groove 176 is preferably a downwardly convex curved shape. The lower portion 171 and the bottom portion 175 are preferably smoothly connected. The bottom portion 175 may include the same material as the lower portion 171.

As described above, since the lens 170 further includes the bottom portion 175, it is possible to improve the filling property of the filling resin with respect to the valley portion between the adjacent lenses 170.

### [Modification 5]

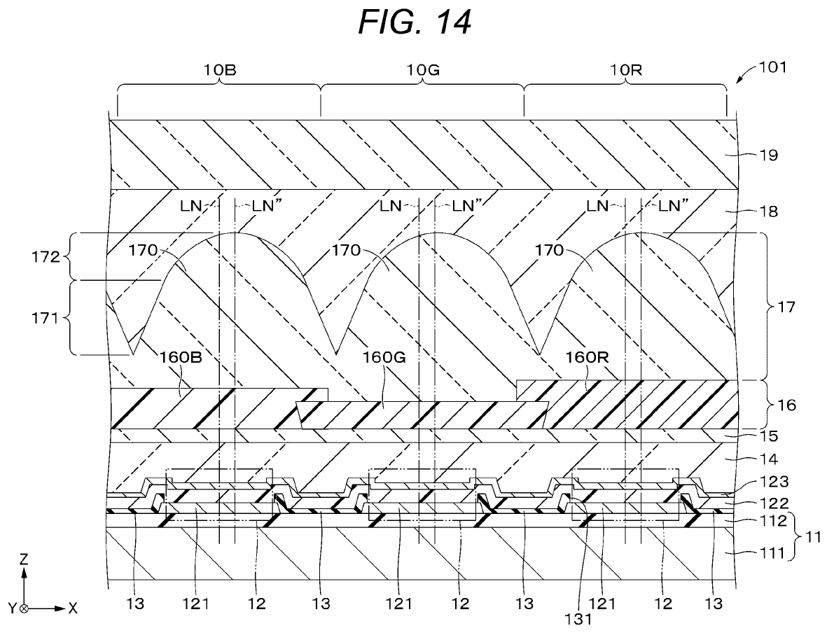

As illustrated in FIG. 14, central axes LN″ of at least some lenses 170 included in the lens array 17 may be shifted in the in-plane direction (direction perpendicular to the central axis LN″) of the first surface of the drive substrate 11 with reference to a central axis LN of the light emitting element 12. As described above, since the central axes LN″ of the lenses 170 are shifted in the in-plane direction of the first surface of the drive substrate 11, the emission direction of the light from the lens 170 can be controlled. Note that the central axes of at least some of the colored layers 160 included in the color filter 16 may be shifted in the in-plane direction (direction perpendicular to the central axis LN″) of the first surface of the drive substrate 11 with reference to the central axis LN of the light emitting element 12.

### [Modification 6]

In one embodiment, an example in which a plurality of subpixels 10 is delta-arrayed has been described. However, the array pattern of the plurality of subpixels 10 is not limited to this example. The plurality of subpixels 10 may be arrayed, for example, in a square array or a stripe array.

### (Example of Square Array)

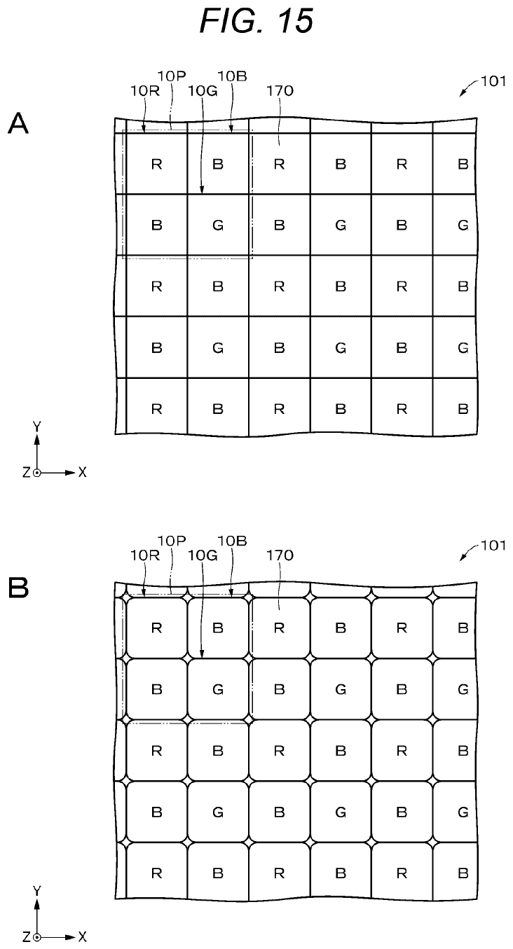

In a case where the array pattern of the plurality of subpixels 10 is a square array, as illustrated in FIG. 15A, one pixel 10P may include four subpixels 10R, 10G, 10B, and 10B. The subpixel 10R and the subpixel 10G included in one pixel 10P may be arranged so as to be adjacent to each other in an oblique direction, and the subpixel 10B and the subpixel 10B included in one pixel 10P may be arranged so as to be adjacent to each other in an oblique direction. However, a type and an arrangement of the subpixels 10 configuring the square array are not limited to this example.

The subpixel 10 may have a square shape in plan view as illustrated in FIG. 15A, or may have a square shape with rounded corners as illustrated in FIG. 15B. The bottom surface of the lens 170 may have a square shape in plan view as illustrated in FIG. 15A, or may have a square shape with rounded corners as illustrated in FIG. 15B. The square shape is an example of a quadrangular shape. Note that FIGS. 15A and 15B illustrate an example in which the bottom surface shape of the lens 170 and the shape of the subpixel 10 are the same in plan view, and the sizes of the bottom surface of the lens 170 and the subpixel 10 are the same. In order to reduce the area of the gap between the adjacent lenses 170, the sides of the bottom surfaces of the adjacent lenses 170 are preferably in contact with each other in plan view.

### (Example of Stripe Array)

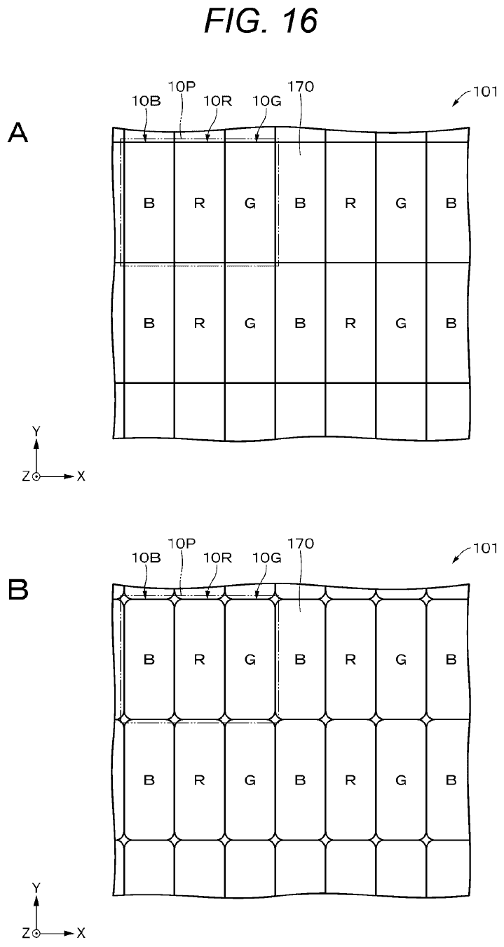

In a case where the array pattern of the plurality of subpixels 10 is a stripe array, as illustrated in FIG. 16A, one pixel 10P may include three subpixels 10R, 10G, and 10B.

The subpixel 10 may have a rectangular shape in plan view as illustrated in FIG. 16A, or may have a rectangular shape with rounded corners as illustrated in FIG. 16B. The bottom surface of the lens 170 may have a rectangular shape in plan view as illustrated in Fig. 16A, or may have a rectangular shape with rounded corners as illustrated in FIG. 16B. The rectangular shape is an example of a quadrangular shape. Note that FIGS. 16A and 16B illustrate an example in which the bottom surface shape of the lens 170 and the shape of the subpixel 10 are the same in plan view, and the sizes of the bottom surface of the lens 170 and the subpixel 10 are the same. In order to reduce the area of the gap between the adjacent lenses 170, the sides of the bottom surfaces of the adjacent lenses 170 are preferably in contact with each other in plan view.

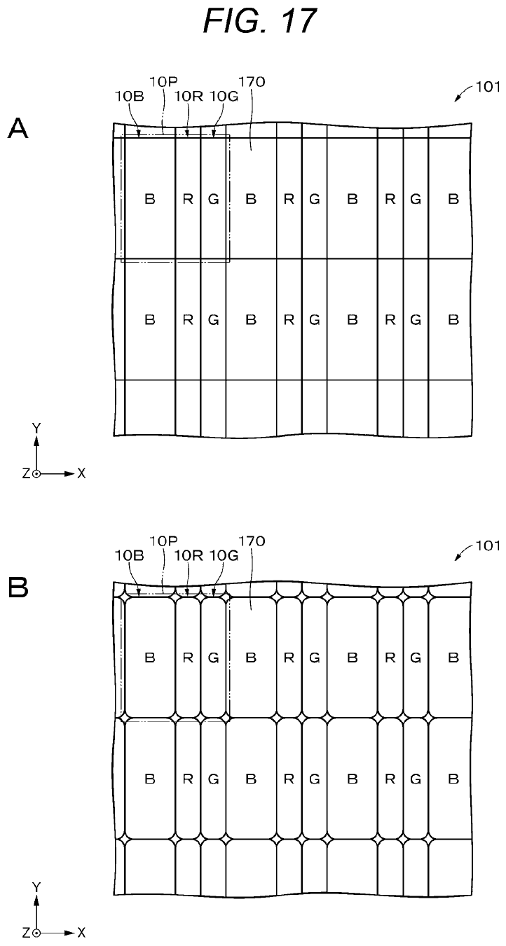

FIGS. 16A and 16B illustrate an example in which the sizes of the three subpixels 10R, 10G, and 10B are the same. However, the sizes of the three subpixels 10R, 10G, and 10B are not limited to this example, and may be different. For example, as illustrated in FIGS. 17A and 17B, the sizes of the subpixels 10R and 10G in the X-axis direction may be smaller than the size of the subpixel 10B in the X-axis direction. Similarly, the sizes of the lenses 170 provided in each of the three subpixels 10R, 10G, and 10B may be different.

FIGS. 17A and 17B illustrate an example in which the sizes of the subpixels 10R, 10G, and 10B arrayed in the stripe array are different, but the sizes of the delta-arrayed subpixels 10R, 10G, and 10B or the square-arrayed subpixels 10R, 10G, 10B, 10B, and the like may be different. Similarly, the sizes of the lenses 170 provided in the delta-arrayed subpixels 10R, 10G, and 10B may be different from each other, or the sizes of the lenses 170 provided in the square-arrayed subpixels 10R, 10G, 10B, and 10B may be different from each other.

### [Modification 7]

In one embodiment, an example in which the shape of the subpixel 10 and the shape of the bottom surface of the lens 170 in plan view are hexagonal has been described. Furthermore, in Modification 6, an example in which the shape of the subpixel 10 and the shape of the bottom surface of the lens 170 in plan view are square or rectangular has been described. However, the shape of the subpixel 10 and the shape of the bottom surface of the lens 170 in plan view are not limited to these examples, and may be, for example, a circular shape or an elliptical shape as illustrated in FIG. 18.

However, in a case where the subpixel 10 has a circular shape or an elliptical shape, when the adjacent subpixels 10 are brought close to each other, the adjacent subpixels 10 contact with each other at points as illustrated in FIG. 18. On the other hand, in a case where the subpixel 10 has a hexagonal shape, a square shape, or a rectangular shape, in a case where the adjacent subpixels 10 are brought close to each other, as illustrated in FIGS. 3A, 15A, and 16A, the subpixels 10 contact with each other on sides. Therefore, from the viewpoint of reducing the area of the gap between the adjacent subpixels 10, the shape of the subpixel 10 in plan view is preferably a hexagonal shape, a square shape, or a rectangular shape. Similarly, from the viewpoint of reducing the area of the gap between the adjacent lenses 170, the shape of the lens 170 in plan view is preferably a hexagonal shape, a square shape, or a rectangular shape.

### [Modification 8]

In one embodiment, an example in which the filling resin layer 18 and the substrate 19 are sequentially provided on the first surface of the lens array 17 has been described. However, the configuration of the display device 101 is not limited to this example, and the filling resin layer 18 and the substrate 19 may not be provided on the first surface of the lens array 17, and the first surface of the lens array 17 may be released.

### [Modification 9]

The light emitting element 12 may have a resonator structure from the viewpoint of improving light extraction efficiency and/or improving color purity. In the present specification, the term “and/or” means “at least one”, and for example, in a case where the term is used in a phrase “X and/or Y”, this phrase means three cases of “only X”, “only Y”, and “X and Y”.

In a case where the first electrode 121 is a reflective electrode having a function as a reflective layer, the resonator structure may be configured by the first electrode 121 and the second electrode 123. In this case, an optical distance between the first electrode 121 and the second electrode 123 may be set by the thickness of the OLED layer 122, may be set by selecting the material of the first electrode 121, or may be set by a combination thereof.

In a case where the first electrode 121 is a transparent electrode, a reflective layer may be provided below the transparent electrode, and the reflective layer and the second electrode 123 may configure the resonator structure. In this case, the optical distance between the reflective layer and the second electrode 123 may be set by the thickness of the OLED layer 122, may be set by selecting the material of the reflective layer, may be set by the thickness of the insulating layer provided between the first electrode 121 (transparent electrode) and the reflective layer, or may be set by a combination of two or more thereof.

### [Modification 10]

In one embodiment, an example has been described in which the display device 101 includes the plurality of light emitting elements 12 capable of emitting white light and the color filter 16, and a color image can be displayed by a combination thereof. However, the method of coloring the display device 101 is not limited thereto. For example, instead of the plurality of light emitting elements 12, the display device 101 may include a plurality of light emitting elements capable of emitting red light, a plurality of light emitting elements capable of emitting green light, and a plurality of light emitting elements capable of emitting blue light. In this case, the color filter may or may not be provided.

Examples of the light emitting element include, for example: (1) a light emitting element including a light emitting layer capable of emitting light of a predetermined color (red light, green light, or blue light); (2) a light emitting element including a light emitting layer capable of emitting white light, the light emitting element being capable of resonating and emphasizing light of a predetermined wavelength (red light, green light, or blue light) included in the white light emitted by the light emitting layer by a resonator structure; and (3) a light emitting element including a light emitting layer capable of emitting light of a predetermined color (red light, green light, or blue light), the light emitting element being capable of resonating and emphasizing light of a predetermined wavelength included in the light of the predetermined color emitted by the light emitting layer by a resonator structure.

### [Modification 11]

In one embodiment, an example in which the color filter 16 is provided has been described, but a quantum dot layer may be provided instead of the color filter 16, or a quantum dot layer may be provided together with the color filter 16. The quantum dot layer includes quantum dots (semiconductor particles), and can convert the color of light emitted from the plurality of light emitting elements. In this case, the plurality of light emitting elements 12 may be configured to be able to emit blue light.

### [Modification 12]

In one embodiment, an example in which the light emitting element 12 is an OLED element has been described, but the light emitting element is not limited to this example, and may be, for example, a light emitting element or the like of a self light emitting type such as a light emitting diode (LED) element, an inorganic electro-luminescence (IEL) element, a quantum dot light emitting diode (QLED) element, a semiconductor laser element, or the like. The display device may be provided with two or more types of light emitting elements.

### [Other Modifications]

Although one embodiment and modifications thereof (hereinafter, referred to as “one embodiment and the like”) of the present disclosure have been specifically described above, the present disclosure is not limited to one embodiment and the like, and various modifications based on the technical idea of the present disclosure can be made.

For example, configurations, methods, processes, shapes, materials, numerical values, and the like in one embodiment and the like are merely examples, and different configurations, methods, processes, shapes, materials, numerical values, and the like may be employed as necessary.

The configurations, methods, processes, shapes, materials, numerical values, and the like of one embodiment and the like can be combined with each other without departing from the gist of the present disclosure.

Furthermore, the materials exemplified in one embodiment and the like can be used alone or in combination of two or more unless otherwise specified.

Furthermore, the present disclosure can also adopt the following configurations.

(1)

A display device including:
a plurality of light emitting elements arrayed two-dimensionally; and
a plurality of lenses provided to respectively correspond to the plurality of light emitting elements, in which
the lens includes a lower portion having a tapered side surface and an upper portion having a convex curved surface.
   (2)

The display device according to (1), in which
an inclination angle O of the side surface is 45°<θ<90°.
   (3)

The display device according to (1) or (2), in which
the upper portion and the lower portion include a Same material.
   (4)

The display device according to any one of (1) to (3), in which
peripheral edges of bottom surfaces of adjacent lenses are in contact with each other in plan view.
   (5)

The display device according to any one of (1) to (3), in which
the plurality of lenses has a substantially quadrangular shape or a substantially hexagonal shape in plan view, and
sides of bottom surfaces of adjacent lenses are in contact with each other in plan view.
   (6)

The display device according to any one of (1) to (5), in which
at least some lenses of the plurality of lenses are shifted in an in-plane direction with reference to the light emitting elements.
   (7)

The display device according to any one of (1) to (6), further including:
a resin layer covering the plurality of lenses, in which
a refractive index of the lens is larger than a refractive index of the resin layer.
   (8)

The display device according to any one of (1) to (7), in which
the plurality of lenses is arranged such that lens surfaces are on a side opposite to the light emitting element side.
   (9)

The display device according to any one of (1) to (7), in which
the plurality of lenses is arranged such that lens surfaces are on the light emitting element side.
   (10)

The display device according to any one of (1) to (10), in which
the lens further includes a bottom portion having a curved side surface, and
the curved side surface has a gentler inclination than the side surface of the lower portion.
   (11)

The display device according to any one of (1) to (10), in which
at least some lenses of the plurality of lenses have irregularities on surfaces.
   (12)

The display device according to any one of (1) to (11), further including a color filter, in which the plurality of lenses is provided between the plurality of light emitting elements and the color filter.

(13)

The display device according to any one of (1) to (12), in which
the plurality of light emitting elements includes organic light emitting diode elements.
   (14)

An electronic apparatus including the display device according to any one of (1) to (13).

### 5 Relationship Among Normal Lines Passing Through Centers of Each of Light Emitting Unit, Lens Member, and Wavelength Selection Unit>

Hereinafter, a relationship among a normal line LN passing through a center of a light emitting unit, a normal line LN′ passing through a center of a lens member, and a normal line LN″ passing through a center of a wavelength selection unit will be described. Here, the light emitting unit is, for example, the light emitting element 12 in one embodiment and the like. The lens member is, for example, the lens 170 in one embodiment and the like. The wavelength selection unit is, for example, the colored layer 160 in one embodiment and the like.

Note that the size of the wavelength selection unit may be appropriately changed according to the light emitted from the light emitting unit, or in a case where a light absorbing unit (for example, black matrix unit) is provided between the wavelength selection units of adjacent light emitting units, the size of the light absorbing unit may be appropriately changed according to the light emitted from the light emitting unit. Furthermore, the size of the wavelength selection unit may be changed as appropriate in accordance with a distance (offset amount) d₀ between the normal line passing through the center of the light emitting unit and the normal line passing through the center of the wavelength selection unit. The planar shape of the wavelength selection unit may be the same as, similar to, or different from the planar shape of the lens member.

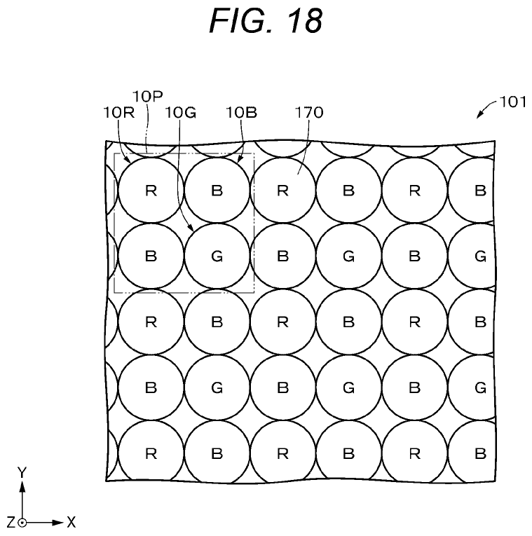

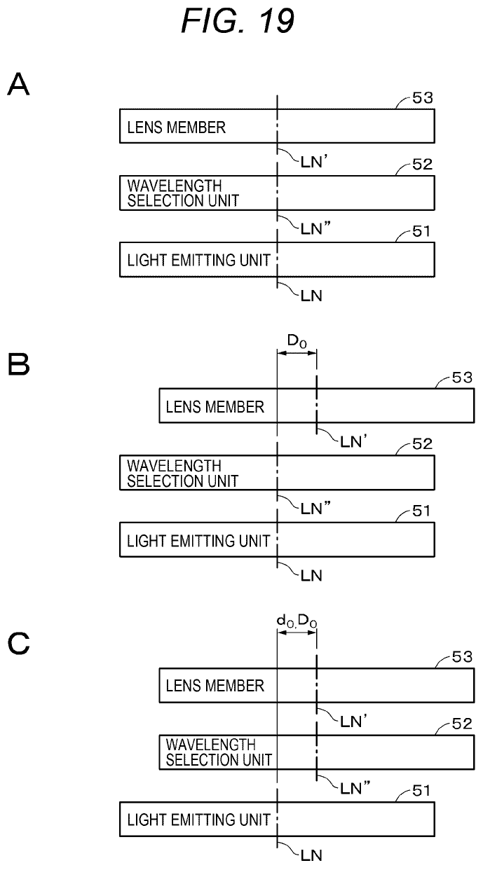

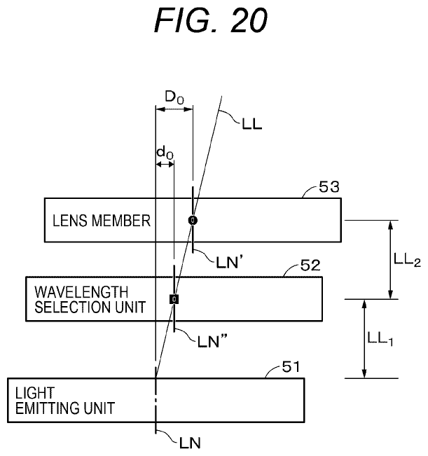

Hereinafter, with reference to FIGS. 19A, 19B, 19C, and 20, a relationship among the normal lines passing through the center of each unit in a case where the light emitting unit 51, the wavelength selection unit 52, and the lens member 53 are arranged in this order will be described.

As illustrated in FIG. 19A, the normal line LN passing through the center of the light emitting unit 51, the normal line LN″ passing through the center of the wavelength selection unit 52, and the normal line LN′ passing through the center of the lens member 53 may coincide with each other. That is, D₀=0 and d₀=0 may be satisfied. Here, Do represents a distance (offset amount) between the normal line LN passing through the center of the light emitting unit 51 and the normal line LN′ passing through the center of the lens member 53, and d₀ represents a distance (offset amount) between the normal line LN passing through the center of the light emitting unit 51 and the normal line LN″ passing through the center of the wavelength selection unit 52.

As illustrated in FIG. 19B, it may be configured such that the normal line LN passing through the center of the light emitting unit 51 and the normal line LN″ passing through the center of the wavelength selection unit 52 coincide with each other, but the normal line LN passing through the center of the light emitting unit 51 and the normal line LN″ passing through the center of the wavelength selection unit 52 do not coincide with the normal line LN′ passing through the center of the lens member 53. That is, D₀>0 and d₀=0 may be satisfied.

As illustrated in FIG. 19C, it may be configured such that the normal line LN passing through the center of the light emitting unit 51 does not coincide with the normal line LN″ passing through the center of the wavelength selection unit 52 and the normal line LN′ passing through the center of the lens member 53, and the normal line LN″ passing through the center of the wavelength selection unit 52 coincides with the normal line LN′ passing through the center of the lens member 53. That is, D₀>0, d₀>0, and D₀=d₀ may be satisfied.

As illustrated in FIG. 20, it may be configured such that the normal line LN passing through the center of the light emitting unit 51, the normal line LN″ passing through the center of the wavelength selection unit 52, and the normal line LN′ passing through the center of the lens member 53 do not coincide with each other. That is, D₀>0, d₀>0, and D₀≠d₀ may be satisfied. Here, the center of the wavelength selection unit 52 (position indicated by a black square in FIG. 20) is preferably located on a straight line LL connecting the center of the light emitting unit 51 and the center of the lens member 53 (position indicated by a black circle in FIG. 20). Specifically, assuming that a distance in the thickness direction (vertical direction in FIG. 20) between the center of the light emitting unit 51 and the center of the wavelength selection unit 52 is denoted as LL₁, and that a distance in the thickness direction between the center of the wavelength selection unit 52 and the center of the lens member 53 is denoted as LL₂, it is preferable that

D₀>d₀>0

is satisfied, and with manufacturing variations being taken into consideration,

d₀:D₀=LL₁:(LL₁+LL₂)

is satisfied.

Here, the thickness direction represents the thickness direction of the light emitting unit 51, the wavelength selection unit 52, and the lens member 53.

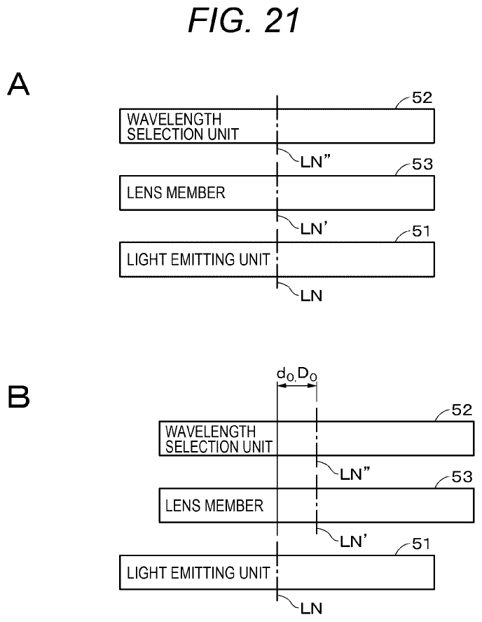

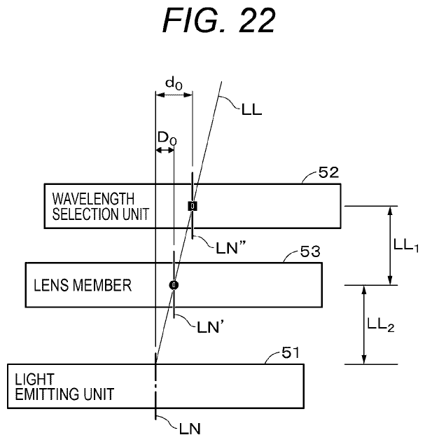

Hereinafter, with reference to FIGS. 21A, 21B, and 22, a relationship among the normal lines passing through the centers of the units in a case where the light emitting unit 51, the lens member 53, and the wavelength selection unit 52 are arranged in this order will be described.

As illustrated in FIG. 21A, it may be configured such that the normal line LN passing through the center of the light emitting unit 51, the normal line LN″ passing through the center of the wavelength selection unit 52, and the normal line LN′ passing through the center of the lens member 53 coincide with each other. That is, D₀>0 and d₀=0 may be satisfied.

As illustrated in FIG. 21B, it may be configured such that the normal line LN passing through the center of the light emitting unit 51 does not coincide with the normal line LN″ passing through the center of the wavelength selection unit 52 and the normal line LN′ passing through the center of the lens member 53, and the normal line LN″ passing through the center of the wavelength selection unit 52 coincides with the normal line LN′ passing through the center of the lens member 53. That is, D₀>0, d₀>0, and D₀=d₀ may be satisfied.

As illustrated in FIG. 22, it may be configured such that the normal line LN passing through the center of the light emitting unit 51, the normal line LN″ passing through the center of the wavelength selection unit 52, and the normal line LN′ passing through the center of the lens member 53 do not coincide with each other. Here, the center of the lens member 53 (position indicated by a black circle in FIG. 22) is preferably located on the straight line LL connecting the center of the light emitting unit 51 and the center of the wavelength selection unit 52 (position indicated by a black square in FIG. 22). Specifically, assuming that a distance in the thickness direction (vertical direction in FIG. 22) between the center of the light emitting unit 51 and the center of the lens member 53 is denoted as LL₂, and that a distance in the thickness direction between the center of the lens member 53 and the center of the wavelength selection unit 52 is denoted as LL₁, it is preferable that

d₀>D₀>0

is satisfied, and with manufacturing variations being taken into consideration,

D₀:d₀=LL₂:(LL₁+LL₂)

is satisfied.

Here, the thickness direction represents the thickness direction of the light emitting unit 51, the wavelength selection unit 52, and the lens member 53.

### 6 Example of Resonator Structure

The subpixel 10 included in the display device 101 according to one embodiment and the like may have a configuration including a resonator structure that resonates light generated by the light emitting element 12. Hereinafter, the resonator structure will be described with reference to the drawings. Furthermore, in the following description, the first surface of each layer may be referred to as an upper surface.

### (Resonator Structure: First Example)

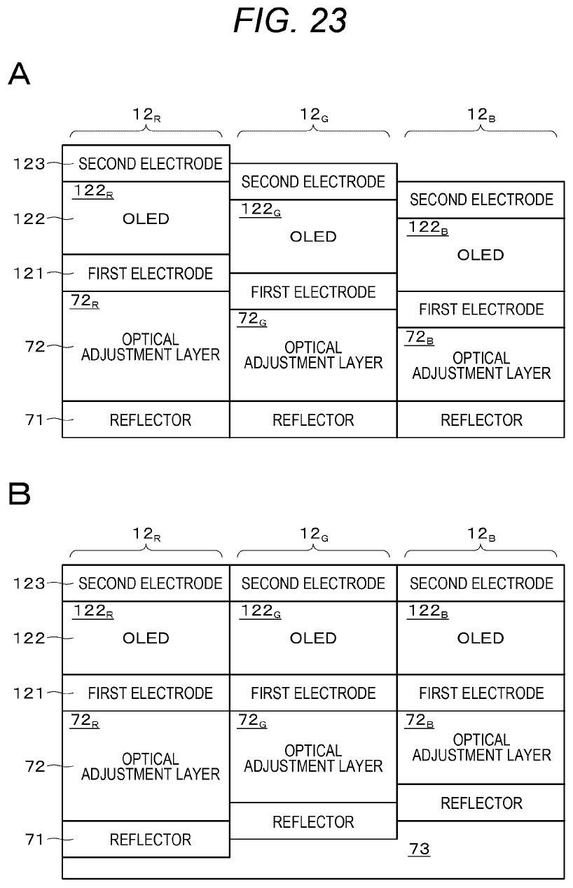

FIG. 23A is a schematic cross-sectional view for describing a first example of a resonator structure. Note that, in the following description, the light emitting elements provided to respectively correspond to the subpixels 10R, 10G, and 10B may be simply referred to as light emitting elements 12 in a case where they are collectively referred to without being particularly distinguished. In a case of distinguishing between the light emitting elements provided to respectively correspond to the subpixels 10R, 10G, and 10B, the light emitting elements may be referred to as light emitting elements 12_{R}, 12_{G}, and 12_{B}. Portions of the OLED layer 122 respectively corresponding to the subpixels 10R, 10G, and 10B may be referred to as an OLED layer 122_{R}, an OLED layer 122_{G}, and an OLED layer 122_{B}.

In the first example, the first electrode 121 is formed in each of the light emitting elements 12 with a common film thickness. This similarly applies to the second electrode 123.

A reflector 71 is arranged below the first electrode 121 of the light emitting element 12 with an optical adjustment layer 72 interposed therebetween. A resonator structure that causes resonance of light generated by the OLED layer 122 is formed between the reflector 71 and the second electrode 123. In the following description, the optical adjustment layers 72 provided to respectively correspond to the subpixels 10R, 10G, and 10B may be referred to as optical adjustment layers 72_{R}, 72_{G}, and 72_{B}.

The reflector 71 is formed in each of the light emitting elements 12 with a common film thickness. The film thickness of the optical adjustment layer 72 varies depending on a color to be displayed by the subpixel. Since the optical adjustment layers 72_{R}, 72_{G}, and 72_{B} have different film thicknesses, it is possible to set an optical distance that causes optimum resonance for a wavelength of light corresponding to the color to be displayed.

In the example illustrated in FIG. 23A, the upper surfaces of the reflectors 71 in the light emitting elements 12_{R}, 12_{G}, and 12_{B} are arranged so as to be aligned. As described above, since the film thickness of the optical adjustment layer 72 varies depending on the color to be displayed by the subpixel, the position of the upper surface of the second electrode 123 varies depending on the types of the light emitting elements 12_{R}, 12_{G}, and 12_{B}.

The reflector 71 can be formed using a metal such as aluminum (Al), silver (Ag), copper (Cu), or the like, or an alloy containing these as main components, for example.

The optical adjustment layer 72 can include an inorganic insulating material such as silicon nitride (SiNₓ), silicon oxide (SiOₓ), or silicon oxynitride (SiOₓN_{y}), or an organic resin material such as an acrylic resin or a polyimide resin. The optical adjustment layer 72 may be a single layer, or may be a multilayer film including the plurality of materials. Furthermore, the number of layers may vary depending on the type of the light emitting element 12.

The first electrode 121 can be formed using a transparent conductive material such as indium tin oxide (ITO), indium zinc oxide (IZO), or zinc oxide (ZnO).

The second electrode 123 needs to function as a semi-transparent reflective film. The second electrode 123 can be formed using magnesium (Mg), silver (Ag), a magnesium-silver alloy (MgAg) containing these as main components, an alloy containing an alkali metal or an alkaline earth metal, or the like.

### (Resonator Structure: Second Example)

FIG. 23B is a schematic cross-sectional view for describing a second example of the resonator structure.

In the second example as well, the first electrode 121 and the second electrode 123 are each formed with a common film thickness in each of the light emitting elements 12.

Then, in the second example as well, the reflector 71 is arranged below the first electrode 121 of the light emitting element 12 with the optical adjustment layer 72 interposed therebetween. A resonator structure that causes resonance of light generated by the OLED layer 122 is formed between the reflector 71 and the second electrode 123. Similarly to the first example, the reflector 71 is formed with a common film thickness in each of the light emitting elements 12, and the film thickness of the optical adjustment layer 72 varies depending on the color to be displayed by the subpixel.

In the first example illustrated in FIG. 23A, the upper surfaces of the reflectors 71 in the light emitting elements 12_{R}, 12_{G}, and 12_{B} are arranged so as to be aligned, and the positions of the upper surfaces of the second electrodes 123 vary depending on the types of the light emitting elements 12_{R}, 12_{G}, and 12_{B}.

On the other hand, in the second example illustrated in FIG. 23B, the upper surfaces of the second electrodes 123 are arranged so as to be aligned across the light emitting elements 12_{R}, 12_{G}, and 12_{B}. In order to align the upper surfaces of the second electrodes 123, the upper surfaces of the reflectors 71 in the light emitting elements 12_{R}, 12_{G}, and 12_{B} are arranged so as to vary depending on the types of the light emitting elements 12_{R}, 12_{G}, and 12_{B}. Therefore, the lower surfaces of the reflectors 71 (in other words, the upper surface of the underlayer (insulating layer) 73) form a stair shape according to the types of the light emitting elements 12.

Materials or the like configuring the reflector 71, the optical adjustment layer 72, the first electrode 121, and the second electrode 123 are similar to those described in the first example, and thus, the description thereof will be omitted.

### (Resonator Structure: Third Example)

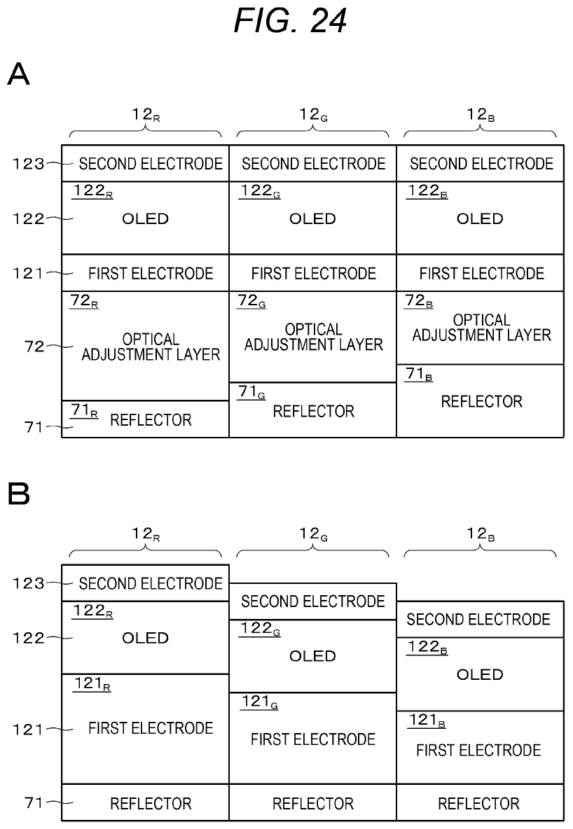

FIG. 24A is a schematic cross-sectional view for describing a third example of the resonator structure. In the following description, the reflectors 71 provided to respectively correspond to the subpixels 10R, 10G, and 10B may be referred to as reflectors 71_{R}, 71_{G}, and 71_{B}.

In the third example as well, the first electrode 121 and the second electrode 123 are formed with a common film thickness in each of the light emitting elements 12.

Then, in the third example as well, the reflector 71 is arranged below the first electrode 121 of the light emitting element 12 with the optical adjustment layer 72 interposed therebetween. A resonator structure that causes resonance of light generated by the OLED layer 122 is formed between the reflector 71 and the second electrode 123. Similarly to the first and the second examples, the film thickness of the optical adjustment layer 72 varies depending on a color to be displayed by the subpixel. Then, similarly to the second example, the upper surfaces of the second electrodes 123 are arranged so as to be aligned across the light emitting elements 12_{R}, 12_{G}, and 12_{B}.

In the second example illustrated in FIG. 24B, in order to align the upper surfaces of the second electrodes 123, the lower surfaces of the reflectors 71 form a stair shape according to the types of the light emitting elements 12.

On the other hand, in the third example illustrated in FIG. 24A, the film thickness of the reflector 71 is set to vary depending on the types of the light emitting elements 12_{R}, 12_{G}, and 12_{B}. More specifically, the film thickness is set such that the lower surfaces of the reflectors 71_{R}, 71_{G}, and 71_{B} are aligned.

Materials or the like configuring the reflector 71, the optical adjustment layer 72, the first electrode 121, and the second electrode 123 are similar to those described in the first example, and thus, the description thereof will be omitted.

### (Resonator Structure: Fourth Example)

FIG. 24B is a schematic cross-sectional view for describing a fourth example of the resonator structure. In the following description, the first electrodes 121 provided to respectively correspond to the subpixels 10R, 10G, and 10B will be referred to as first electrodes 121_{R}, 121_{G}, and 121_{B}.

In the first example illustrated in FIG. 24A, the first electrode 121 and the second electrode 123 of each light emitting element 12 are formed with a common film thickness. Then, the reflector 71 is arranged below the first electrode 121 of the light emitting element 12 with the optical adjustment layer 72 interposed therebetween.

On the other hand, in the fourth example illustrated in FIG. 24B, the optical adjustment layer 72 is omitted, and the film thickness of the first electrode 121 is set to vary depending on the types of the light emitting elements 12_{R}, 12_{G}, and 12_{B}.

The reflector 71 is formed in each of the light emitting elements 12 with a common film thickness. The film thickness of the first electrode 121 varies depending on a color to be displayed by the subpixel. Since the first electrodes 121_{R}, 121_{G}, and 121_{B} have different film thicknesses, it is possible to set an optical distance that causes optimum resonance for a wavelength of light corresponding to the color to be displayed.

Materials or the like configuring the reflector 71, the optical adjustment layer 72, the first electrode 121, and the second electrode 123 are similar to those described in the first example, and thus, the description thereof will be omitted.

### (Resonator Structure: Fifth Example)

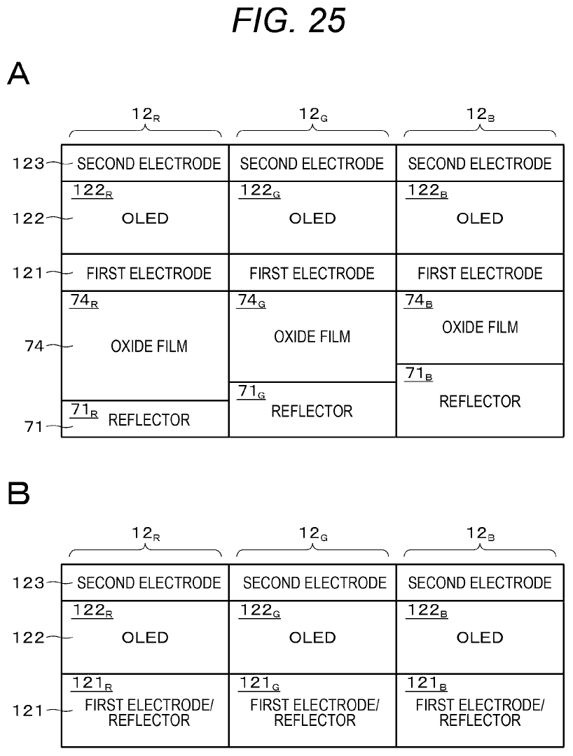

FIG. 25A is a schematic cross-sectional view for describing a fifth example of the resonator structure.

In the first example illustrated in FIG. 23A, the first electrode 121 and the second electrode 123 are each formed with a common film thickness in each of the light emitting elements 12. Then, the reflector 71 is arranged below the first electrode 121 of the light emitting element 12 with the optical adjustment layer 72 interposed therebetween.

On the other hand, in the fifth example illustrated in FIG. 25A, the optical adjustment layer 72 is omitted, and instead, an oxide film 74 is formed on the surface of the reflector 71. The film thickness of the oxide film 74 is set to vary depending on the types of the light emitting elements 12_{R}, 12_{G}, and 12_{B}. In the following description, the oxide films 74 provided to respectively correspond to the subpixels 10R, 10G, and 10B are referred to as oxide films 74_{R}, 74_{G}, and 74_{B}.

The film thickness of the oxide film 74 varies depending on the color to be displayed by the subpixel. Since the oxide films 74_{R}, 74_{G}, and 74_{B} have different film thicknesses, it is possible to set an optical distance that causes optimum resonance for a wavelength of light corresponding to the color to be displayed.

The oxide film 74 is a film obtained by oxidizing the surface of the reflector 71, and is configured using, for example, aluminum oxide, tantalum oxide, titanium oxide, magnesium oxide, zirconium oxide, or the like. The oxide film 74 functions as an insulating film for adjusting the optical path length (optical distance) between the reflector 71 and the second electrode 123.

The oxide films 74 having film thicknesses that vary depending on the types of the light emitting elements 12_{R}, 12_{G}, and 12_{B} can be formed, for example, as follows.

First, an electrolytic solution is filled in a container, and a substrate on which the reflector 71 is formed is immersed in the electrolytic solution. Furthermore, an electrode is arranged to face the reflector 71.

Then, a positive voltage is applied to the reflector 71 with reference to the electrode to anodize the reflector 71. A film thickness of the oxide film obtained as a result of the anodization is proportional to a voltage value for the electrode. Therefore, the anodization is performed with a voltage determined according to the types of the light emitting elements 12 applied to each of the reflectors 71_{R}, 71_{G}, and 71_{B}. As a result, the oxide films 74 having different film thicknesses can be collectively formed.

Materials or the like configuring the reflector 71, the first electrode 121, and the second electrode 123 are similar to those described in the first example, and thus, the description thereof will be omitted.

### (Resonator Structure: Sixth Example)

FIG. 25B is a schematic cross-sectional view for describing a sixth example of the resonator structure.

In the sixth example, the light emitting element 12 is configured by laminating the first electrode 121, the OLED layer 122, and the second electrode 123. However, in the sixth example, the first electrode 121 is formed to function as both an electrode and a reflector. The first electrode (/reflector) 121 includes a material having an optical constant selected according to the types of the light emitting elements 12_{R}, 12_{G}, and 12_{B}. Since a phase shift caused by the first electrode (/reflector) 121 varies, it is possible to set the optical distance that causes optimum resonance for the wavelength of light corresponding to the color to be displayed.

The first electrode (/reflector) 121 can be configured using a single metal such as aluminum (Al), silver (Ag), gold (Au), copper (Cu), or the like, or an alloy containing these metals as main components. For example, the first electrode (/reflector) 121_{R} of the light emitting element 12_{R} can include copper (Cu), and the first electrode (/reflector) 121_{G} of the light emitting element 12_{G} and the first electrode (/reflector) 121_{B} of the light emitting element 12_{B} can include aluminum.

The materials or the like configuring the second electrode 123 are similar to those described in the first example, and thus the description thereof will be omitted.

### (Resonator Structure: Seventh Example)

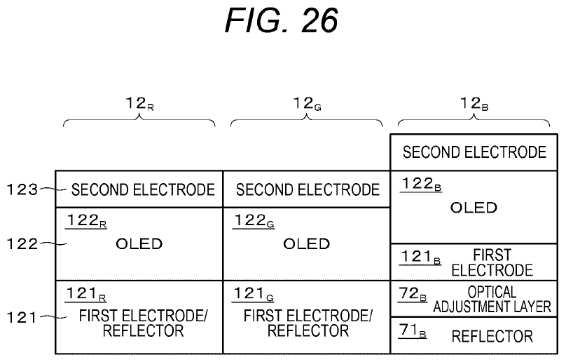

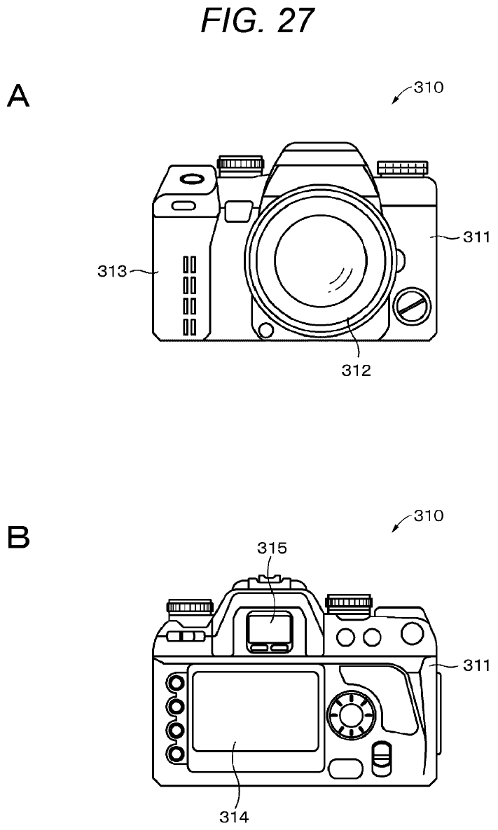

FIG. 26 is a schematic cross-sectional view for describing a seventh example of the resonator structure.

The seventh example basically has a configuration in which the sixth example is applied for the light emitting elements 12_{R} and 12_{G}, and the first example is applied for the light emitting element 12_{B}. Also in this configuration, it is possible to set the optical distance that causes optimum resonance for the wavelength of light corresponding to the color to be displayed.

The first electrodes (/reflectors) 121_{R} and 121_{G} used for the light emitting elements 12_{R} and 12_{G} can include a single metal such as aluminum (Al), silver (Ag), gold (Au), copper (Cu), or the like, or an alloy containing these as main components.

Materials or the like configuring the reflector 71_{B}, the optical adjustment layer 72_{B}, and the first electrode 121_{B} used for the light emitting element 12_{B} are similar to those described in the first example, and thus the description thereof will be omitted.

### 7 Application Examples

### (Electronic Apparatus)

The display device 101 according to one embodiment and the like may be provided in various electronic apparatuses. The display device 101 of one embodiment and the like are suitable especially for an eyewear device such as a head-mounted display, an electronic viewfinder of a video camera or a single-lens reflex camera, or the like that requires high resolution and is used near the eyes in an enlarged manner.

### (Specific Example 1)

FIGS. 27A and 27B illustrate an example of an external appearance of a digital still camera 310. The digital still camera 310 is of a lens interchangeable single-lens reflex type, and includes an interchangeable imaging lens unit (interchangeable lens) 312 substantially at the center of the front of a camera main body portion (camera body) 311, and a grip portion 313 to be held by a person who images an image on the front left side.

A monitor 314 is provided at a position shifted to the left from the center of the back surface of the camera main body portion 311. An electronic viewfinder (eyepiece window) 315 is provided above the monitor 314. By looking into the electronic view finder 315, the person who images an image can determine composition by visually recognizing the optical image of a subject guided from the imaging lens unit 312. The electronic view finder 315 includes any one of the display devices 101 according to one embodiment and the like.

### (Specific Example 2)

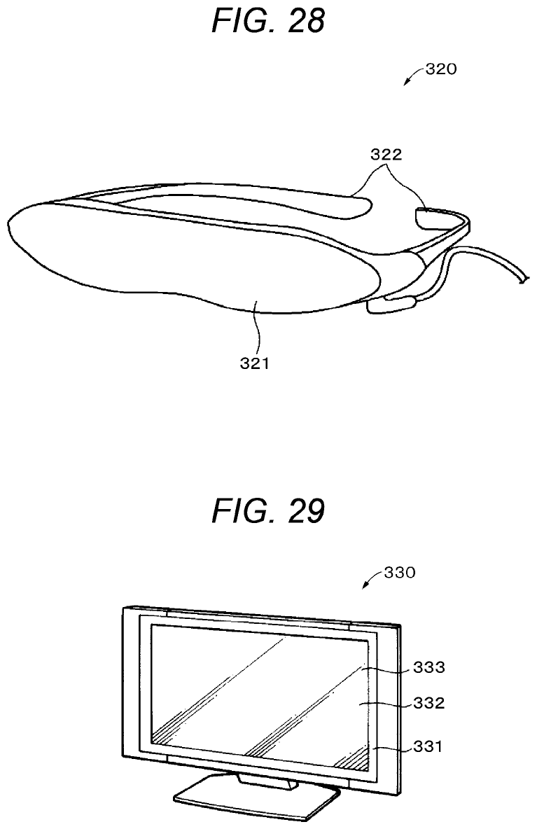

FIG. 28 illustrates an example of an external appearance of a head-mounted display 320. The head-mounted display 320 is an example of an eyewear device. The head-mounted display 320 includes, for example, ear hooking portions 322 to be worn on the head of the user on both sides of a glass-shaped display unit 321. The display unit 321 includes any one of the display devices 101 according to one embodiment and the like.

### (Specific Example 3)

FIG. 29 illustrates an example of an external appearance of a television device 330. The television device 330 includes a video display screen unit 331 including a front panel 332 and a filter glass 333, and the video display screen unit 331 is provided with any one of the display devices 101 according to one embodiment and the like, for example.

### (Specific Example 4)

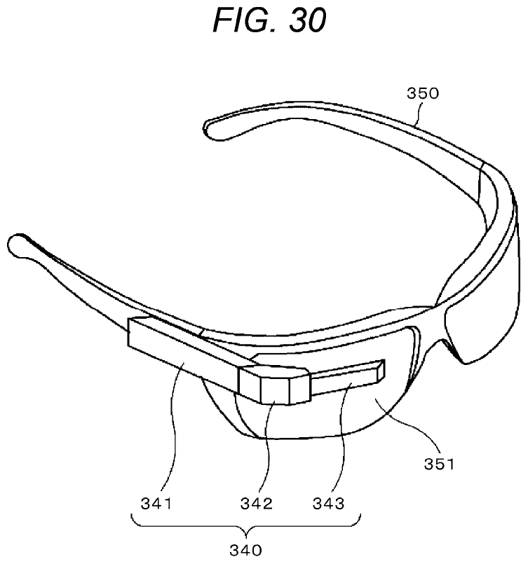

FIG. 30 illustrates an example of an external appearance of a see-through head-mounted display 340. The see-through head-mounted display 340 is an example of an eyewear device. The see-through head-mounted display 340 includes a main body portion 341, an arm 342, and a lens barrel 343.

The main body portion 341 is coupled to the arm 342 and eyeglasses 350. Specifically, an end portion of the main body portion 341 in a long side direction is coupled to the arm 342, and one side of a side surface of the main body portion 341 is connected to the eyeglasses 350 via a coupling member. Note that the main body portion 341 may be directly mounted on the head of the human body.

The main body portion 341 incorporates a control board for controlling operation of the see-through head-mounted display 340, and a display unit. The arm 342 couples the main body portion 341 and the lens barrel 343, and supports the lens barrel 343. Specifically, the arm 342 is coupled to an end portion of the main body portion 341 and an end portion of the lens barrel 343, and fixes the lens barrel 343. Furthermore, the arm 342 incorporates a signal line for communicating data related to an image to be provided from the main body portion 341 to the lens barrel 343.

The lens barrel 343 projects image light provided from the main body portion 341 via the arm 342 toward the eyes of the user wearing the see-through head-mounted display 340 through an eyepiece 351. In the see-through head-mounted display 340, the display unit of the main body portion 341 includes any one of the display devices 101 according to one embodiment and the like.

### (Specific Example 5)

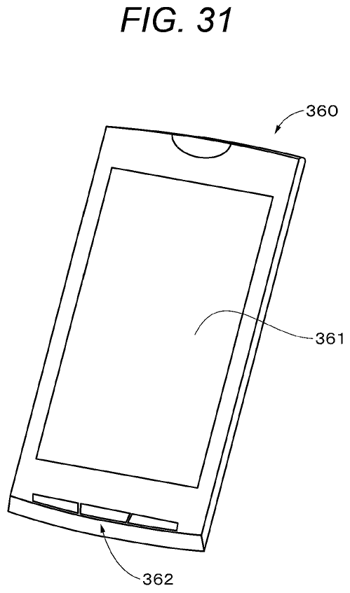

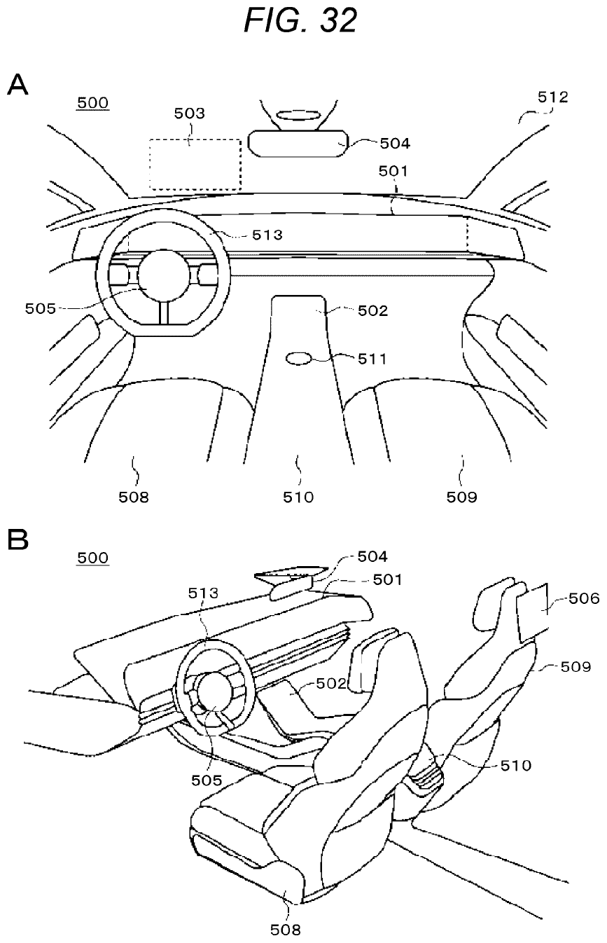

FIG. 31 illustrates an example of an external appearance of a smartphone 360. The smartphone 360 includes a display unit 361 that displays various kinds of information, an operation unit 362 including a button or the like for receiving operation input from the user, and the like. The display unit 361 includes any one of the display devices 101 according to one embodiment and the like.

### (Specific Example 6)

The display device 101 according to one embodiment and the like may be provided in various displays provided in a vehicle.

FIGS. 32A and 32B are views illustrating an example of an internal configuration of a vehicle 500 provided with various displays. Specifically, FIG. 32A is a view illustrating an example of an internal state of the vehicle 500 from the rear to the front of the vehicle 500, and FIG. 32B is a view illustrating an example of an internal state of the vehicle 500 from the oblique rear to the oblique front of the vehicle 500.

The vehicle 500 includes a center display 501, a console display 502, a head-up display 503, a digital rearview mirror 504, a steering wheel display 505, and a rear entertainment display 506. At least one of these displays includes any one of the display devices 101 according to one embodiment and the like. For example, all of these displays may include any of the display devices 101 and the like according to one embodiment and the like.

The center display 501 is arranged on the dashboard at a location facing a driver's seat 508 and a passenger's seat 509. FIGS. 32A and 32B illustrate an example of the center display 501 having a horizontally long shape extending from the driver's seat 508 side to the passenger's seat 509 side, but the screen size and the arrangement place of the center display 501 are arbitrary. The center display 501 can display information detected by various sensors. As a specific example, the center display 501 can display an image imaged by an image sensor, an image of a distance to an obstacle present in front of or on a side of the vehicle 500, the distance being measured by a ToF sensor, a body temperature of the occupant detected by an infrared sensor, or the like. The center display 501 can be used to display at least one piece of safety-related information, operation-related information, lifelogs, health-related information, authentication/identification-related information, or entertainment-related information, for example.

The safety-related information is information about doze sensing, looking-away sensing, sensing of mischief of a child riding together, presence or absence of wearing of a seat belt, sensing of leaving of an occupant, and the like, and is information sensed by a sensor arranged in an overlapping manner on the back surface side of the center display 501, for example. The operation-related information detects a gesture related to the operation of an occupant using the sensor. Gestures to be detected may include operations of various types of equipment in the vehicle 500. For example, operations of air conditioning equipment, a navigation device, an AV device, a lighting device, and the like are detected. The lifelogs include lifelogs of all the occupants. For example, the lifelogs include an action record of each occupant in the vehicle. By acquiring and storing the lifelogs, it is possible to check the state of each occupant at the time of an accident. The health-related information is information obtained by estimating the health condition of the occupant on the basis of the body temperature of the occupant sensed by a sensor such as a temperature sensor. Alternatively, the face of the occupant may be imaged by using an image sensor, and the health condition of the occupant may be estimated from the imaged facial expression. Moreover, a conversation may be made with the occupant in automatic voice, and the health condition of the occupant may be estimated on the basis of the contents of a response from the occupant. The authentication/identification-related information includes information regarding a keyless entry function of performing face authentication by using a sensor, a function of automatically adjusting a seat height and position through face identification, and the like. The entertainment-related information includes a function of detecting operation information of the AV device by an occupant using the sensor, a function of recognizing the face of an occupant by the sensor and providing content suitable for the occupant by the AV device, and the like.

The console display 502 can be used to display lifelog information, for example. The console display 502 is arranged near a shift lever 511 of a center console 510 between the driver's seat 508 and the passenger's seat 509. The console display 502 can also display information detected by various sensors. Furthermore, the console display 502 may display an image of the surroundings of the vehicle imaged by an image sensor, or may display an image of the distance to an obstacle present in the surroundings of the vehicle.

The head-up display 503 is virtually displayed behind a windshield 512 in front of the driver's seat 508. The head-up display 503 can be used to display at least one piece of the safety-related information, the operation-related information, the lifelogs, the health-related information, the authentication/identification-related information, or the entertainment-related information, for example. Since the head-up display 503 is virtually arranged in front of the driver's seat 508 in many cases, it is suitable for displaying information directly related to the operation of the vehicle 500 such as a speed of the vehicle 500, a remaining amount of fuel (battery), and the like.

The digital rearview mirror 504 can not only display the rear of the vehicle 500 but also display the state of an occupant in the rear seat, and thus, can be used to display the lifelog information by arranging a sensor on the back surface side of the digital rearview mirror 504 in an overlapping manner, for example.

The steering wheel display 505 is arranged near the center of a steering wheel 513 of the vehicle 500. The steering wheel display 505 can be used to display at least one piece of the safety-related information, the operation-related information, the lifelogs, the health-related information, the authentication/identification-related information, or the entertainment-related information, for example. In particular, since the steering wheel display 505 is close to the driver's hand, it is suitable for displaying lifelog information such as the body temperature of the driver, or for displaying information regarding the operation of an AV device, an air conditioning equipment, or the like.

The rear entertainment display 506 is attached to the back side of the driver's seat 508 or the passenger's seat 509, and is for an occupant in the rear seat to enjoy viewing/listening. The rear entertainment display 506 can be used to display at least one piece of the safety-related information, the operation-related information, the lifelogs, the health-related information, the authentication/identification-related information, or the entertainment-related information, for example. In particular, being located in front of the occupant in the rear seat, the rear entertainment display 506 displays information related to the occupant in the rear seat. For example, information regarding an operation of the AV device or the air conditioning equipment may be displayed, or a result of measurement of the body temperature or the like of an occupant in the rear seat with a temperature sensor may be displayed.

It may be configured such that a sensor is arranged on the back surface side of a display device 101 and the like in an overlapping manner, and the distance to an object present in the surroundings can be measured in the configuration. Optical distance measurement methods are roughly classified into a passive type and an active type. By the method of the passive type, distance measurement is performed by receiving light from an object, without projecting light from a sensor to the object. The method of the passive type includes a lens focus method, a stereo method, a monocular vision method, and the like. By the method of the active type, distance measurement is performed by projecting light to an object, and receiving reflected light from the object with a sensor to measure the distance. The method of the active type includes an optical radar method, an active stereo method, an illuminance difference stereo method, a moire topography method, an interference method, and the like. The display device 101 according to one embodiment and the like can be applied to any of these types of distance measurement. By using the sensor arranged to overlap the back surface side of the display device 101, the above-described passive type or active type distance measurement can be performed.

### REFERENCE SIGNS LIST

10R, 10G, 10B Subpixel
11 Drive substrate
111 Substrate
112 Insulating layer
113 Pad portion
12 Light emitting element
121 First electrode
122 OLED layer
123 Second electrode
13 Insulating layer
131 Opening
14 Protective layer
15 Flattening layer
16 Color filter
160R, 160G, 160B Colored layer
17 Lens array
170 Lens
170a Structure
171 Lower portion
172 Upper portion
173 First photosensitive resin layer
174 Second photosensitive resin layer
175 Bottom portion
176 Groove
18 Filling resin layer
19 Substrate
101 Display device
310 Digital still camera
320 Head-mounted display
330 Television device
340 See-through head-mounted display
360 Smartphone
500 Vehicle
RE1 Effective pixel region
RE2 Peripheral region

1. A display device comprising:
a plurality of light emitting elements arrayed two-dimensionally; and
a plurality of lenses provided to respectively correspond to the plurality of light emitting elements, wherein
the lens includes a lower portion having a tapered side surface and an upper portion having a convex curved surface.

2. The display device according to claim 1, wherein
an inclination angle θ of the side surface is 45°<θ<90°.

3. The display device according to claim 1, wherein
the upper portion and the lower portion include a same material.

4. The display device according to claim 1, wherein
peripheral edges of bottom surfaces of adjacent lenses are in contact with each other in plan view.

5. The display device according to claim 1, wherein
the plurality of lenses has a substantially quadrangular shape or a substantially hexagonal shape in plan view, and
sides of bottom surfaces of adjacent lenses are in contact with each other in plan view.

6. The display device according to claim 1, wherein
at least some lenses of the plurality of lenses are shifted in an in-plane direction with reference to the light emitting elements.

7. The display device according to claim 1, further comprising:
a resin layer covering the plurality of lenses, wherein
a refractive index of the lens is larger than a refractive index of the resin layer.

8. The display device according to claim 1, wherein
the plurality of lenses is arranged such that lens surfaces are on a side opposite to the light emitting element side.

9. The display device according to claim 1, wherein
the plurality of lenses is arranged such that lens surfaces are on the light emitting element side.

10. The display device according to claim 1, wherein
the lens further includes a bottom portion having a curved side surface, and
the curved side surface has a gentler inclination than the side surface of the lower portion.

11. The display device according to claim 1, wherein
at least some lenses of the plurality of lenses have irregularities on surfaces.

12. The display device according to claim 1, further comprising a color filter, wherein
the plurality of lenses is provided between the plurality of light emitting elements and the color filter.

13. The display device according to claim 1, wherein
the plurality of light emitting elements includes organic light emitting diode elements.

14. An electronic apparatus comprising the display device according to claim 1.
